(19) United States
(12) Patent Application Publication
(10) Pub. No.: US 2024/0297646 A1
(43) Pub. Date: Sep. 5, 2024

(54) Spiking Neuron Circuit System and Spiking Neuron Circuit

(71) Applicant: JAPAN SCIENCE AND TECHNOLOGY AGENCY, Saitama (JP)

(72) Inventor: Takeaki Yajima, Fukuoka-shi, Fukuoka (JP)

(21) Appl. No.: 18/574,771

(22) PCT Filed: Jun. 16, 2022
(86) PCT No.: PCT/JP2022/024189

§ 371 Date: Dec. 28, 2023

(30) Foreign Application Priority Data
Jul. 2, 2021 (JP) 2021-111124

(51) Int. Cl. H03K 17/687; H03K 19/20

(52) U.S. Cl. CPC H03K 17/687; H03K 19/20

(57) ABSTRACT

A spiking neuron circuit system includes: a charging circuit that, when an input voltage is applied, starts charging of a capacitor by an output current of a field effect transistor; a pulse generation circuit that generates and outputs a pulse signal when a charged voltage of the capacitor reaches a first predetermined value; and a control circuit that controls the output current of the field effect transistor by controlling at least one of a bulk voltage or a gate voltage of the field effect transistor.

### TECHNICAL FIELD

The present disclosure relates to a spiking neuron circuit system, and more particularly, to a spiking neuron circuit system having a waiting time from when an input voltage is applied to when a pulse signal is output. The present disclosure also relates to a spiking neuron circuit that can be used in such a spiking neuron circuit system.

### BACKGROUND ART

Spiking neuron circuits that more faithfully mimic firing signals of biological neurons have been proposed. In the spiking neuron circuit, a waveform of an output signal becomes a spike-like pulse. WO 2020/175290 describes a spiking neuron circuit having a predetermined waiting time from when an input voltage is applied to when a spike-like pulse signal is output.

In the spiking neuron circuit of WO 2020/175290, a capacitor is charged by an input voltage, and a pulse signal is output when a charged voltage of the capacitor reaches a predetermined value. WO 2020/175290 describes a matter of performing control of a power supply circuit with extremely low power consumption by performing timing control of the power supply circuit by using a pulse signal output from the spiking neuron circuit.

### SUMMARY OF INVENTION

When the spiking neuron circuit is mounted on an integrated circuit, characteristics of each element in the circuit are different from design values due to influences of a manufacturing process, arrangement of the elements, an operating temperature, and the like. Therefore, there is a possibility that the design value and the actual value are different also in a waiting time from when the input voltage is applied to the spiking neuron circuit to when the pulse signal is output.

When the design value and the actual value are different from each other, a technical problem may occur. For example, when the timing control of the power supply circuit is performed by using the pulse signal output from the spiking neuron circuit as in WO 2020/175290, if the design value and the actual value of the waiting time are greatly different from each other, the control of the power supply circuit may be hindered.

The problem is not limited to this, and various other problems may also occur. For example, even when a time interval between pulses of a pulse sequence output from the spiking neuron circuit is modulated and transmitted according to information to be transmitted, the design value and the actual value of the time interval are different from each other, which may cause a problem that the information is received as different information on a receiving side.

The present disclosure is to solve the above problem, and an object thereof is to provide a spiking neuron circuit system capable of controlling a waiting time from when an input voltage is applied to when a pulse signal is output with high accuracy.

In order to solve the above problem, a spiking neuron circuit system according to the present disclosure includes: a charging circuit that, when an input voltage is applied, starts charging of a capacitance component by an output current of a field effect transistor; a pulse generation circuit that generates and outputs a pulse signal when a charged voltage of the capacitance component reaches a first predetermined value; and a control circuit that controls the output current of the field effect transistor by controlling at least one of a bulk voltage or a gate voltage of the field effect transistor.

The control circuit may include a control voltage generation circuit that generates a control voltage for controlling the at least one of the bulk voltage or the gate voltage of the field effect transistor.

The control circuit may further include a selection signal generation circuit that generates a selection signal for generation of the control voltage by the control voltage generation circuit. The selection signal generation circuit may have a storage circuit that stores information for generating the selection signal.

The control circuit may discretely control the at least one of the bulk voltage or the gate voltage of the field effect transistor.

The control voltage generation circuit may include a plurality of diodes connected in series in a forward direction between a first power supply line and a second power supply line, and generate any one of voltages generated at respective nodes between the diodes as the control voltage.

The control voltage generation circuit may include a capacitor, and generate a charged voltage of the capacitor as the control voltage.

The spiking neuron circuit system may further include a reference signal circuit that outputs a reference signal when a predetermined time elapses after the input voltage is applied, and the control circuit may compensate for a waiting time from when the input voltage is applied to when the pulse signal is output based on a time difference between a timing at which the reference signal is output and a timing at which the pulse signal is output.

A variation of the predetermined time with respect to a temperature change is smaller than a variation of the waiting time with respect to a temperature change.

The charging circuit may be mounted on a semiconductor substrate. The spiking neuron circuit system may further include a time constant circuit that includes a resistor and a capacitor configured by individual elements externally attached to the semiconductor substrate and that charges the capacitor with a predetermined time constant, and the reference signal circuit may output the reference signal when a charged voltage of the capacitor reaches a second predetermined value.

The spiking neuron circuit system may further include a switch that controls power supply to the resistor and the capacitor, and the switch may allow power supply to the resistor and the capacitor only when compensating for the waiting time.

The control circuit may switch a voltage to be supplied to at least one of a bulk terminal or a gate terminal of the field effect transistor, in stages, until a time difference between a timing at which the reference signal is output and a timing at which the pulse signal is output becomes equal to or less than a third predetermined value.

The control circuit may further include a control voltage generation circuit that generates a control voltage for controlling the at least one of the bulk voltage or a gate voltage of the field effect transistor, and includes a selection signal generation circuit that generates a selection signal for generation of the control voltage by the control voltage generation circuit, and may end compensation for the waiting time when a time difference between a timing at which the reference signal is output and a timing at which the pulse signal is output becomes equal to or less than the third predetermined value. The selection signal generation circuit may have a storage circuit that stores information for generating the selection signal, and may store the information for generating the selection signal at the end of the compensation for the waiting time in the storage circuit.

The capacitance component of the charging circuit may include a parasitic capacitance of a transistor.

The control circuit may control the output current of the field effect transistor by controlling the bulk voltage.

The field effect transistor may be an N-channel type, and the control circuit may control the bulk voltage in a range of −VDD to 0.4 VDD, when VDD is a power supply voltage of the spiking neuron circuit system.

The field effect transistor may be a P-channel type, and the control circuit may control the bulk voltage in a range of 0.6 VDD to 2 VDD, when VDD is a power supply voltage of the spiking neuron circuit system.

The control circuit may control the output current of the field effect transistor by controlling the gate voltage.

The control circuit may control the gate voltage in a range of 0 to VDD, when VDD is a power supply voltage of the spiking neuron circuit system.

The pulse generation circuit may have a positive feedback loop and a negative feedback loop.

The positive feedback loop may steepen a rise of the pulse signal, and the negative feedback loop may steepen a fall of the pulse signal.

The pulse generation circuit may include a plurality of inverters connected in cascade. Each of the plurality of inverters may include a P-channel field effect transistor and an N-channel field effect transistor that are complementarily turned on, and channel width ratios of the P-channel field effect transistor and the N-channel field effect transistor may be different from each other between adjacent inverters.

The spiking neuron circuit system may further include: a timing control circuit that outputs a standby signal; and a plurality of output control circuits, each of which corresponds to at least one of the pulse generation circuits, and each of which outputs an output signal having a state that transitions at a timing corresponding to a pulse signal output from the corresponding pulse generation circuit, and holds a state of the output signal during a standby period indicated by the standby signal when the standby signal is input.

The spiking neuron circuit system may include a switching element connected to the capacitance component. A pulse signal sequence may be output from the pulse generation circuit by repeating charging of the capacitance component by the charging circuit and discharging of the capacitance component by the switching element. The control circuit may control a pulse interval of the pulse signal sequence output from the pulse generation circuit.

The control circuit may control the pulse interval of the pulse signal sequence based on information to be transmitted.

The information to be transmitted may be a time-varying input signal.

A spiking neuron circuit according to the present disclosure includes a charging circuit that, when an input voltage is applied, starts charging of a capacitance component by an output current of a field effect transistor; a plurality of inverters connected between an input node connected to the capacitance component and an output node from which a pulse signal is output; and a switching element provided between the input node and a first reference voltage and having a control terminal connected to the output node, in which the spiking neuron circuit does not have a feedback loop that feeds back from coupling points between inverters in the plurality of inverters to the input node.

A first-stage inverter of the plurality of inverters may include a first switching element provided between the first reference voltage and an intermediate output node, and a second switching element provided between the intermediate output node and a second reference voltage. A first diode may be connected in a forward direction between the first reference voltage and the first switching element, and a second diode may be connected in a forward direction between the second switching element and the second reference voltage.

The spiking neuron circuit according to claim 27 may further include a comparator having one input terminal connected to the input node, the other input terminal connected to a predetermined intermediate potential between the first reference voltage and the second reference voltage, and an output terminal connected to an input terminal of the first-stage inverter of the plurality of inverters.

The charging circuit may include a plurality of capacitors, and a voltage determined according to a capacitance ratio of the plurality of capacitors may be applied to a gate terminal of the field effect transistor.

According to the spiking neuron circuit system according to the present disclosure, it is possible to control a waiting time from when an input voltage is applied to when a pulse signal is output with high accuracy.

### BRIEF DESCRIPTION OF DRAWINGS

FIG. 1 is a diagram illustrating a configuration of a spiking neuron circuit system according to a first embodiment.

FIG. 2 is a diagram illustrating an internal configuration of a first-stage inverter of a pulse generation circuit according to the first embodiment.

FIG. 3 is a diagram illustrating an internal configuration of a control circuit according to the first embodiment.

FIG. 4 is a diagram illustrating an internal configuration of an activation circuit according to the first embodiment.

FIG. 5 is a diagram illustrating an internal configuration of an input generation circuit according to the first embodiment.

FIG. 6 is a diagram illustrating an internal configuration of a reset generation circuit according to the first embodiment.

FIG. 7 is a diagram illustrating an internal configuration of a match determination circuit according to the first embodiment.

FIG. 8 is a diagram illustrating an internal configuration of a long/short determination circuit according to the first embodiment.

FIG. 9 is a diagram illustrating an internal configuration of a selection signal generation circuit according to the first embodiment.

FIG. 10 is a diagram illustrating an internal configuration of a control voltage generation circuit according to the first embodiment.

FIG. 11 is a timing chart illustrating an example of a normal operation of the spiking neuron circuit system according to the first embodiment.

FIG. 12 is a flowchart illustrating an operation of the control circuit during a waiting time compensation operation of a spiking neuron circuit according to the first embodiment.

FIG. 13 is a timing chart illustrating an example of a waiting time compensation operation of the spiking neuron circuit system according to the first embodiment.

FIG. 14 is a diagram illustrating a configuration of a spiking neuron circuit system according to a second embodiment.

FIG. 15 is a diagram illustrating an internal configuration of a selection signal generation circuit according to the second embodiment.

FIG. 16 is a diagram illustrating an internal configuration of a control voltage generation circuit according to the second embodiment.

FIG. 17 is a timing chart illustrating an example of a waiting time compensation operation of the spiking neuron circuit system according to the second embodiment.

FIG. 18 is a diagram illustrating a configuration of a spiking neuron circuit system according to a third embodiment.

FIG. 19 is a diagram illustrating an internal configuration of a control voltage generation circuit according to the third embodiment.

FIG. 20 is a diagram illustrating a configuration of a spiking neuron circuit system according to a fourth embodiment.

FIG. 21 is a diagram illustrating an internal configuration of a control voltage generation circuit according to the fourth embodiment.

FIG. 22 is a diagram illustrating a configuration of a charging circuit according to a first modification of a fifth embodiment.

FIG. 23 is a diagram illustrating a configuration of a charging circuit according to a second modification of the fifth embodiment.

FIG. 24 is a diagram illustrating a configuration of a charging circuit according to a third modification of the fifth embodiment.

FIG. 25 is a diagram illustrating a configuration of a charging circuit according to a fourth modification of the fifth embodiment.

FIG. 26 is a diagram illustrating a configuration of a pulse generation circuit according to a first modification of a sixth embodiment.

FIG. 27 is a diagram illustrating a configuration of a pulse generation circuit according to a second modification of the sixth embodiment.

FIG. 28 is a diagram illustrating a configuration of a pulse generation circuit according to a seventh embodiment.

FIG. 29 is a diagram illustrating a configuration of a spiking neuron circuit system according to an eighth embodiment.

FIG. 30 is a diagram illustrating an internal configuration of a control circuit according to the eighth embodiment.

FIG. 31 is a diagram illustrating a correspondence relationship between inputs and outputs of a selection signal generation circuit according to the eighth embodiment.

FIG. 32 is a diagram illustrating an internal configuration of a control voltage generation circuit according to the eighth embodiment.

FIG. 33 is a diagram illustrating an example of a configuration of a control voltage generation circuit according to a ninth embodiment.

FIG. 34A is a diagram illustrating first-stage and second-stage inverters configuring a pulse generation circuit according to a tenth embodiment.

FIG. 34B is a diagram illustrating the first-stage and second-stage inverters configuring the pulse generation circuit according to the tenth embodiment.

FIG. 35 is a diagram illustrating an example of a configuration of a spiking neuron circuit system according to an eleventh embodiment.

FIG. 36 is a diagram illustrating an example of an internal configuration of an output control circuit according to the eleventh embodiment.

FIG. 37 is a timing chart illustrating an example of an operation of the spiking neuron circuit system according to the eleventh embodiment.

FIG. 38 is a diagram illustrating an example of a configuration of a booster circuit controlled by the spiking neuron circuit system according to the eleventh embodiment.

FIG. 39 is a waveform diagram of a current flowing through an inductor.

FIG. 40 is a diagram illustrating an example of a configuration of a charging circuit according to a twelfth embodiment.

### DESCRIPTION OF EMBODIMENTS

Hereinafter, the embodiments of the present disclosure will be described in detail with reference to the drawings. Forms other than the disclosed embodiments may be included in the scope of the claims and various forms that can be practiced by those skilled in the art may also be included in the scope of the claims.

### First Embodiment

### Spiking Neuron Circuit System 100

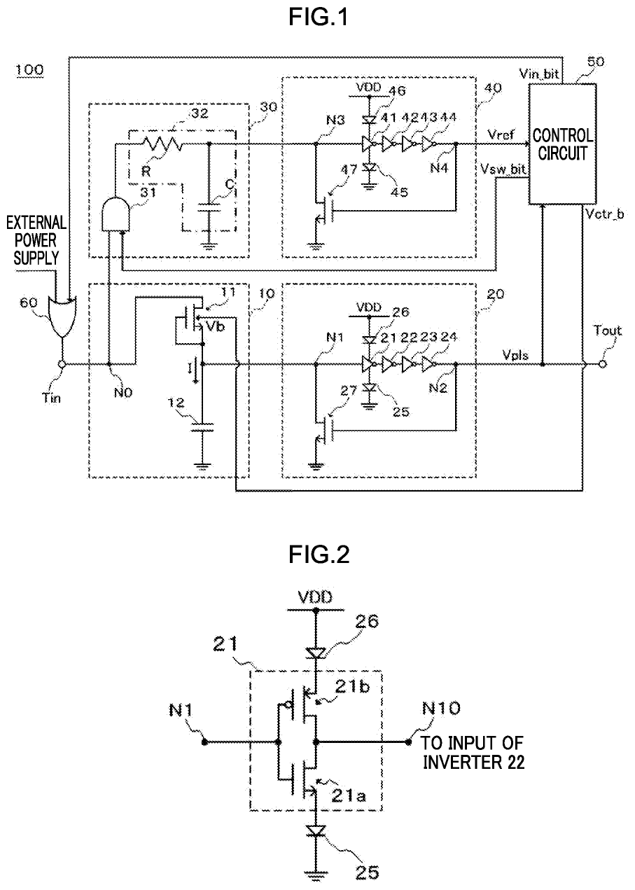

FIG. 1 is a diagram illustrating a configuration of a spiking neuron circuit system 100 according to a first embodiment of the present disclosure. The spiking neuron circuit system 100 includes a charging circuit 10, a pulse generation circuit 20, a CR time constant circuit 30, a reference signal circuit 40, and a control circuit 50.

In FIG. 1, a spiking neuron circuit is configured by the charging circuit 10 and the pulse generation circuit 20. When a predetermined waiting time elapses after an input voltage is applied to an input terminal Tin, the spiking neuron circuit outputs a spike-shaped pulse signal Vpls to an output terminal Tout. However, in the present disclosure, the shape of the pulse signal is not limited to the spike shape, and may be, for example, a rectangular pulse or the like. The spiking neuron circuit is mounted on a semiconductor substrate of an integrated circuit.

As described above, the characteristics of respective elements mounted on the semiconductor substrate of the integrated circuit are different from design values due to the influence of a manufacturing process, an arrangement of the elements, an operating temperature, and the like. Therefore, the design value and the actual value may be different also in the waiting time of the spiking neuron circuit.

The CR time constant circuit 30, the reference signal circuit 40, and the control circuit 50 are circuits for controlling the waiting time of the spiking neuron circuit and compensating such that the actual value of the waiting time matches the design value. These circuits are also mounted on the semiconductor substrate. Note that, only a resistor R and a capacitor C of the CR time constant circuit 30 are configured by individual elements and externally attached to the semiconductor substrate. In FIG. 1, a region 32 surrounded by an alternate long and short dash line represents a region externally attached to the semiconductor substrate.

The spiking neuron circuit system 100 has two operation modes of a normal operation and a waiting time compensation operation. During the normal operation of the spiking neuron circuit system 100, only a part of the spiking neuron circuit configured by the charging circuit 10 and the pulse generation circuit 20 and the control circuit 50 operate. At this time, a DC voltage of 1 V is applied to the input terminal Tin from an external power supply (not shown) via an OR gate 60.

In this regard, during the waiting time compensation operation of the spiking neuron circuit system 100, in addition to the charging circuit 10 and the pulse generation circuit 20, the CR time constant circuit 30, the reference signal circuit 40, and the control circuit 50 also operate. At this time, power is not supplied from the external power supply (not shown), and a compensation input voltage Vin_bit=1 V is applied to the input terminal Tin from the control circuit 50 via the OR gate 60.

### Charging Circuit 10

When an input voltage is applied to the input terminal Tin of the spiking neuron circuit system 100 from the external power supply (not shown) or from the control circuit 50 via the OR gate 60, the charging circuit 10 starts charging the capacitance component by an output current I of the field effect transistor of the charging circuit 10. The input voltage is a DC voltage of 1 V applied from the external power supply (not shown) via the OR gate 60 during the normal operation, and is a compensation input voltage Vin_bit applied from the control circuit 50 via the OR gate 60 during the waiting time compensation operation.

The charging circuit 10 includes a transistor 11, which is an N-channel type MOSFET, and a capacitor 12 as a capacitance component. A drain terminal of the transistor 11 is connected to an input node N0 of the charging circuit 10, and the input node N0 is connected to the input terminal Tin of the spiking neuron circuit system 100. A source terminal of the transistor 11 is connected to one terminal of the capacitor 12 and an input node N1 of the pulse generation circuit 20 described later. In the present first embodiment, the capacitor 12 is a capacitor mounted on the semiconductor substrate. The other terminal of the capacitor 12 is grounded to a ground GND on the semiconductor substrate.

The gate terminal and the source terminal of the transistor 11 are short-circuited. Therefore, a gate-source voltage of the transistor 11 is 0 V, and ideally, the output current I should not flow. However, in an actual MOSFET, even when the gate-source voltage is 0 V, a minute leakage current called a subthreshold current flows. When an input voltage is applied to the input terminal Tin from the external power supply (not shown) or the control circuit 50 via the OR gate 60, the charging circuit 10 starts charging of the capacitor 12 by the subthreshold current of the transistor 11.

In the present disclosure, the term “capacitance component” does not indicate only a capacitor mounted on a semiconductor substrate. For example, a parasitic capacitance of a MOSFET different from the transistor 11 may be used as the capacitance component, or a capacitance of wiring mounted on a semiconductor substrate may be used as the capacitance component. In other words, the term “capacitance component” in the present disclosure is a concept including a capacitor mounted on a semiconductor substrate, a parasitic capacitance of a MOSFET, a capacitance of wiring, and the like.

### Pulse Generation Circuit 20

When the charged voltage of the capacitor 12 of the charging circuit 10 reaches a first predetermined value, the pulse generation circuit 20 generates and outputs a pulse signal Vpls. Specifically, the pulse generation circuit 20 includes four inverters 21 to 24 connected in multiple stages, diodes 25 and 26, and a transistor 27 which is an N-channel MOSFET.

The four inverters 21 to 24 connected in multiple stages function as a delay circuit that delays the signal input to a first-stage inverter 21 by a certain time and outputs the delayed signal from a last-stage inverter 24. For example, when 0 V is input to the first-stage inverter 21, 0 V is output from the last-stage inverter 24 after a certain time delay. When the voltage input to the first-stage inverter 21 rises and reaches a first predetermined value that is a threshold at which the output of the inverter 21 is switched, the output of the first-stage inverter 21 changes from 1 V to 0 V. At this time, 1 V is output from the last-stage inverter 24 after a certain time delay. The number of the inverters connected in multiple stages is not limited to four, and may be any even number. According to the configuration in which the number of the inverters is increased, the gain is increased, the rise of the pulse signal is easily made steeper, and the generation energy of the pulse signal itself can be reduced. As a result, control by the control circuit using the pulse signal can be performed with extremely low power consumption.

Unlike the pulse generation circuit described in WO 2020/175290 described above, there is no feedback loop that feeds back from the connecting points between the inverters in the four inverters 21 to 24 to the input node N1. Therefore, a wiring area of the feedback loop can be reduced, and the circuit can be downsized. Furthermore, it is possible to prevent the feedback loop from picking up electromagnetic induction noise and causing an adverse effect on a circuit operation due to the noise. That is, the waiting time from when the input voltage is applied to when the pulse signal is output can be determined with high accuracy, and control with high accuracy can be performed.

The input of the first-stage inverter 21 is connected to the input node N1 of the pulse generation circuit 20. The output of the last-stage inverter 24 is connected to an output node N2 of the pulse generation circuit 20. The output node N2 is connected to the output terminal Tout of the spiking neuron circuit system 100.

A gate terminal of the transistor 27 is connected to the output node N2. A drain terminal of the transistor 27 is connected to the input node N1, and a source terminal of the transistor 27 is grounded to the ground GND.

When the voltage of the input node N1 rises from 0 V to a first predetermined value, the voltage of the output node N2 becomes 1 V after a certain time delay by the inverters 21 to 24. When the voltage of the output node N2 becomes 1 V, the transistor 27, which is an N-channel type MOSFET, is turned on, and the drain and source of the transistor are electrically connected, so that the voltage of the input node N1 becomes 0 V. When the voltage of the input node N1 becomes 0 V, the voltage of the output node N2 returns to 0 V after a certain time delay by the inverters 21 to 24.

In the pulse generation circuit 20, a path returning to the output node N2 via the output node N2, the transistor 27, the input node N1, and the inverters 21 to 24 configures a delay feedback loop that returns the voltage of the output node N2 to 0 V after a certain time delay when the voltage of the output node N2 becomes 1 V.

FIG. 2 is a diagram illustrating an internal configuration of the first-stage inverter 21 of the pulse generation circuit 20. The inverter 21 includes a transistor 21a which is an N-channel MOSFET and a transistor 21b which is a P-channel MOSFET. The gate terminals of the transistors 21a and 21b are both connected to the input node N1, and the drain terminals of the transistors 21a and 21b are connected to an intermediate output node N10. The intermediate output node N10 is connected to an input of the inverter 22 at a subsequent stage.

A source terminal of the transistor 21a is grounded to the ground GND which is a first reference voltage via the diode 25 connected in the forward direction. A source terminal of the transistor 21b is connected to a power supply line VDD which is a second reference voltage via the diode 26 connected in the forward direction. In the present first embodiment, the voltage of the power supply line VDD is 1 V.

The diodes 25 and 26 are provided to suppress a through current when the transistors 21a and 21b transition from on to off or from off to on. Specifically, an object is to suppress a through current flowing at the time of transition of the transistors 21a and 21b and to reduce power consumption by making a potential difference between both source terminals of the transistors 21a and 21b smaller than a potential difference between the ground GND and the power supply line VDD.

The diodes 25 and 26 may be mounted by forming a PN junction on a semiconductor substrate, but may be mounted by short-circuiting between the gate and drain terminals of another MOSFET different from the transistors 21a and 21b, that is, by diode-connected MOSFETs.

### CR Time Constant Circuit 30

Returning to FIG. 1, the CR time constant circuit 30 charges the capacitor C externally attached to the semiconductor substrate with a predetermined time constant CR when a compensation input voltage Vin_bit=1 V is applied to the input terminal Tin from the control circuit 50 described later via the OR gate 60 during the waiting time compensation operation of the spiking neuron circuit system 100.

Specifically, the CR time constant circuit 30 includes a resistor R and a capacitor C externally attached to the semiconductor substrate, and an AND gate 31 mounted on the semiconductor substrate. One end of the resistor R is connected to an output terminal of the AND gate 31. The other end of the resistor R is connected to one end of the capacitor C and an input node N3 of the reference signal circuit 40 described later.

The other end of the capacitor C is grounded to the ground GND. One input terminal of the AND gate 31 is connected to the input node N0 of the charging circuit 10. A switch control signal Vsw_bit having a value of either 1 V or 0 V is input to the other input terminal of the AND gate 31 from the control circuit 50.

The resistor R is configured by an individual element having high accuracy and excellent temperature characteristics, such as a chip resistor and a metal film resistance. The capacitor C is also configured by an individual element having high accuracy and excellent temperature characteristics, such as a ceramic capacitor or a film capacitor. Therefore, the time constant CR of the CR time constant circuit 30 is more accurate than the time constant determined by the element mounted on the semiconductor substrate.

A variation of the time constant CR determined by the resistor R and the capacitor C externally attached to the semiconductor substrate with respect to the temperature change is also smaller than a variation of the time constant determined by the element mounted on the semiconductor substrate with respect to the temperature change.

The AND gate 31 functions as a switch that controls power supply to the resistor R and the capacitor C. Specifically, during the waiting time compensation operation of the spiking neuron circuit system 100, when the compensation input voltage Vin_bit=1 V is applied to the input terminal Tin via the OR gate 60 and the switch control signal Vsw_bit=1 V, the output of the AND gate 31 becomes 1 V, and power supply to the resistor R and the capacitor C is allowed. As a result, a current flows through the resistor R, and the capacitor C is charged.

In this regard, during the normal operation of the spiking neuron circuit system 100, even when a DC voltage is applied to the input terminal Tin from the external power supply (not shown) via the OR gate 60, as long as the switch control signal Vsw_bit=0 V, the output of the AND gate 31 becomes 0 V, and the power supply to the resistor R and the capacitor C is cut off. As a result, no current flows through the resistor R, and the capacitor C is not charged.

### Reference Signal Circuit 40

The reference signal circuit 40 outputs a reference signal Vref during the waiting time compensation operation of the spiking neuron circuit system 100, when the switch control signal Vsw_bit=1 V, and the charged voltage of the capacitor C of the CR time constant circuit 30, that is, the voltage of the input node N3 reaches a second predetermined value after a predetermined time elapses since the compensation input voltage Vin_bit=1 V is applied to the input terminal Tin.

Here, the reference signal circuit 40 according to the present first embodiment has the same configuration as the pulse generation circuit 20 described above. Therefore, the first predetermined value of the pulse generation circuit 20 is equal to the second predetermined value of the reference signal circuit 40. When the charged voltage of the capacitor C of the CR time constant circuit 30 reaches the second predetermined value equal to the first predetermined value, the reference signal circuit 40 generates and outputs a pulse signal as the reference signal Vref.

Specifically, the reference signal circuit 40 includes four inverters 41 to 44 connected in multiple stages, diodes 45 and 46, and a transistor 47 which is an N-channel MOSFET. An input of the first-stage inverter 41 is connected to the input node N3 of the reference signal circuit 40. An output of the last-stage inverter 44 is connected to an output node N4 of the reference signal circuit 40. The reference signal Vref output from the output node N4 is input to the control circuit 50.

A gate terminal of the transistor 47 is connected to the output node N4. A drain terminal of the transistor 47 is connected to the input node N3, and a source terminal of the transistor 47 is grounded to the ground GND.

### Control Circuit 50

The control circuit 50 controls the output current I of the transistor 11 by controlling a bulk voltage Vb of the transistor 11 included in the charging circuit 10 during the waiting time compensation operation of the spiking neuron circuit system 100.

Specifically, the control circuit 50 compensates for the waiting time based on a time difference between a predetermined time from when the compensation input voltage Vin_bit=1 V is applied to the input terminal Tin to when the reference signal Vref is output by the reference signal circuit 40, and a waiting time from when the compensation input voltage Vin_bit=1 V is applied to the input terminal Tin to when the pulse signal Vpls is output by the pulse generation circuit 20.

More specifically, in a case where a waiting time until the pulse signal Vpls is output is longer than a predetermined time until the reference signal Vref is output, the control circuit 50 increases the output current I of the transistor 11 by controlling the bulk voltage Vb of the transistor 11 included in the charging circuit 10 to be increased. When the output current I of the transistor 11 increases, the time until the charged voltage of the capacitor 12 reaches the first predetermined value is shortened, and the time until the operation of the pulse generation circuit 20 is started is also shortened. As a result, the waiting time from when the compensation input voltage Vin_bit=1 V is applied to the input terminal Tin to when the pulse signal Vpls is output to the output terminal Tout is shortened.

In this regard, when the waiting time until the pulse signal Vpls is output is shorter than the predetermined time until the reference signal Vref is output, the control circuit 50 reduces the output current I of the transistor 11 by controlling the bulk voltage Vb of the transistor 11 included in the charging circuit 10 to be decreased. When the output current I of the transistor 11 decreases, the time until the charged voltage of the capacitor 12 reaches the first predetermined value becomes long, and the time until the operation of the pulse generation circuit 20 is started also increases. As a result, a waiting time from when the compensation input voltage Vin_bit=1 V is applied to the input terminal Tin to when the pulse signal Vpls is output to the output terminal Tout becomes long.

As described above, since the transistor 11 and the capacitor 12 of the charging circuit 10 are mounted on the semiconductor substrate, the characteristics of these elements are susceptible to the manufacturing process, the arrangement of the elements, the operating temperature, and the like. Therefore, the design value and the actual value may be different also in the waiting time until the pulse signal Vpls defined by the charging circuit 10 is output. On the other hand, the resistor R and the capacitor C of the CR time constant circuit 30 are configured by highly accurate individual elements externally attached to the semiconductor substrate. Therefore, an accuracy of the predetermined time until the reference signal Vref defined by the CR time constant circuit 30 is output is higher than an accuracy of the waiting time until the pulse signal Vpls defined by the charging circuit 10 is output.

The control circuit 50 controls the bulk voltage Vb of the transistor 11 included in the charging circuit 10 to perform calibration such that a timing at which the reference signal Vref is output matches a timing at which the pulse signal Vpls is output, thereby compensating for the waiting time from when the compensation input voltage Vin_bit=1 V is applied to when the pulse signal Vpls is output.

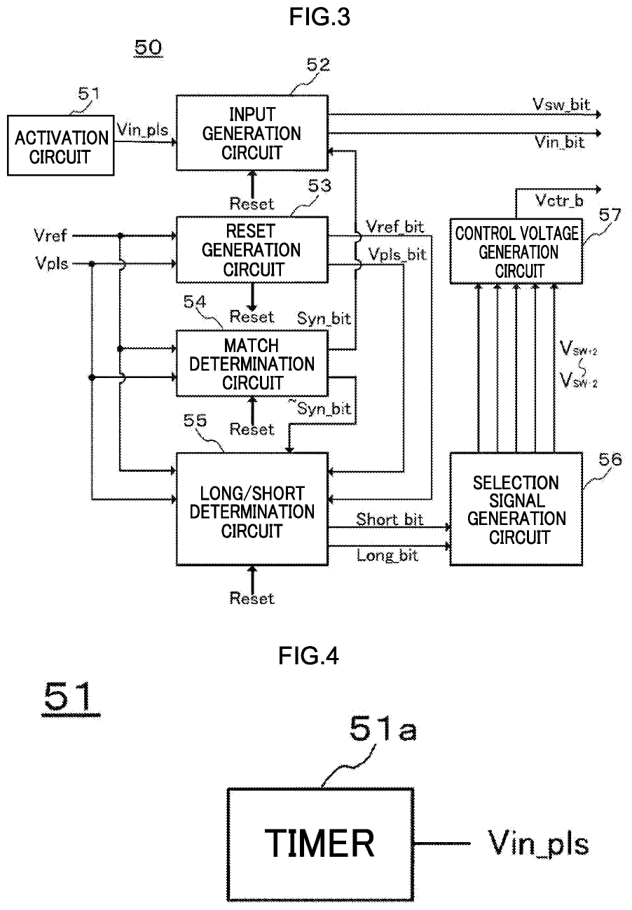

FIG. 3 is a diagram illustrating an internal configuration of the control circuit 50. The control circuit 50 includes an activation circuit 51, an input generation circuit 52, a reset generation circuit 53, a match determination circuit 54, a long/short determination circuit 55, a selection signal generation circuit 56, and a control voltage generation circuit 57.

### Activation Circuit 51

When a predetermined condition is satisfied, the activation circuit 51 activates the control circuit 50 to start the waiting time compensation operation of the spiking neuron circuit system 100. In the present first embodiment, after power supply to the spiking neuron circuit system 100 is started, the activation circuit 51 activates the control circuit 50 every one hour to start the compensation operation.

However, the timing of starting the compensation operation is not limited thereto. The timing of starting the compensation operation may be every several minutes or every several days. Alternatively, the timing of starting the compensation operation may be when the spiking neuron circuit system 100 is powered on, when a significant environmental change is detected, or the like.

FIG. 4 is a diagram illustrating an internal configuration of the activation circuit 51. The activation circuit 51 includes a timer circuit 51a. The timer circuit 51a outputs a pulse-shaped start signal Vin_pls every one hour.

### Input Generation Circuit 52

Returning to FIG. 3, when the start signal Vin_pls is input from the activation circuit 51, the input generation circuit 52 generates and outputs the compensation input voltage Vin_bit=1 V a plurality of times. The input generation circuit 52 outputs the switch control signal Vsw_bit=1 V.

As described above, the compensation input voltage Vin_bit is a voltage applied to the input terminal Tin during the waiting time compensation operation of the spiking neuron circuit system 100. The reference signal circuit 40 outputs the reference signal Vref when a predetermined time elapses after the compensation input voltage Vin_bit is applied to the input terminal Tin. The pulse generation circuit 20 outputs the pulse signal Vpls when a predetermined waiting time elapses after the compensation input voltage Vin_bit is applied to the input terminal Tin.

As described later, the control circuit 50 switches the bulk voltage Vb of the transistor 11 included in the charging circuit 10 in stages until the timing at which the reference signal Vref is output matches the timing at which the pulse signal Vpls is output. The compensation input voltage Vin_bit is output again each time the bulk voltage Vb is switched. The switch control signal Vsw_bit becomes 1 V at the start of the waiting time compensation operation, and continues to be output until the timing at which the reference signal Vref is output matches the timing at which the pulse signal Vpls is output and the compensation operation is completed.

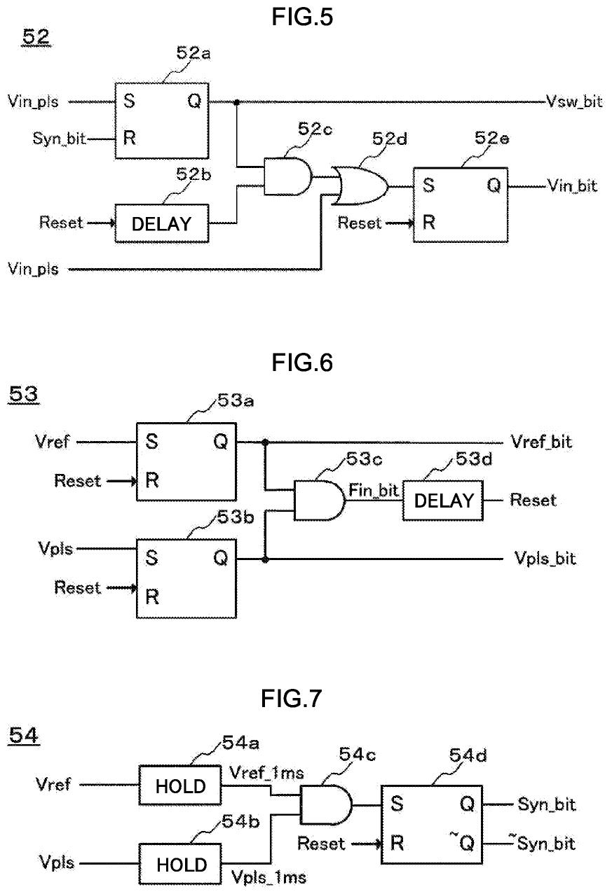

FIG. 5 is a diagram illustrating an internal configuration of the input generation circuit 52. The input generation circuit 52 includes an SR latch 52a, a delay circuit 52b, an AND gate 52c, an OR gate 52d, and an SR latch 52e.

A start signal Vin_pls is input from the activation circuit 51 to an S terminal of the SR latch 52a. A match establishment signal Syn_bit is input to an R terminal of the SR latch 52a from a match determination circuit 54 described later. A switch control signal Vsw_bit is output from a Q terminal of the SR latch 52a. The switch control signal Vsw_bit is also input to one input terminal of the AND gate 52c.

The delay circuit 52b receives a reset signal Reset from a reset generation circuit 54 described later. The reset signal Reset is a pulse-shaped signal that is output once each time a match determination operation described later ends. When a reset signal Reset=1 V is input, the delay circuit 52b outputs the pulse-shaped signal after one microsecond. An output terminal of the delay circuit 52b is connected to the other input terminal of the AND gate 52c.

An output terminal of the AND gate 52c is connected to one input terminal of the OR gate 52d. The start signal Vin_pls is input to the other input terminal of the OR gate 52d. An output terminal of the OR gate 52d is connected to an S terminal of the SR latch 52e. The reset signal Reset is input to an R terminal of the SR latch 52e. A compensation input voltage Vin_bit is output from a Q terminal of the SR latch 52e.

### Reset Generation Circuit 53

Returning to FIG. 3, when one microsecond elapses after both the reference signal Vref output from the reference signal circuit 40 and the pulse signal Vpls output from the pulse generation circuit 20 are output, the reset generation circuit 53 generates and outputs the reset signal Reset=1 V. The reset signal Reset is a signal that temporarily returns the compensation input signal Vin_bit, an expanded reference signal Vref_bit, and an expanded pulse signal Vpls_bit described below to 0 V.

When the reset signal Reset=1 V is output, the compensation input signal Vin_bit temporarily returns to 0 V. The reset signal Reset is repeatedly output every time the bulk voltage Vb of the transistor 11 included in the charging circuit 10 is switched until the timing at which the reference signal Vref is output matches the timing at which the pulse signal Vpls is output.

FIG. 6 is a diagram illustrating an internal configuration of the reset generation circuit 53. The reset generation circuit 53 includes an SR latch 53a, an SR latch 53b, an AND gate 53c, and a delay circuit 53d.

The reference signal Vref is input from the reference signal circuit 40 to an S terminal of the SR latch 53a. The reset signal Reset is re-input to an R terminal of the SR latch 53a. From a Q terminal of the SR latch 53a, the expanded reference signal Vref_bit, whose output is started at the same timing as the reference signal Vref, is output. The expanded reference signal Vref_bit is also input to one input terminal of the AND gate 53c. When the reset signal Reset=1 V is output, the expanded reference signal Vref_bit returns to 0 V.

An S terminal of the SR latch 53b receives the pulse signal Vpls from the pulse generation circuit 20. The reset signal Reset is re-input to an R terminal of the SR latch 53b. The extended pulse signal Vpls_bit, whose output is started at the same timing as the pulse signal Vpls, is output from a Q terminal of the SR latch 53b. The extended pulse signal Vpls_bit is also input to the other input terminal of the AND gate 53c. The extended pulse signal Vpls_bit returns to 0 V when the reset signal Reset=1 V is output.

A Fin_bit signal indicating whether both the reference signal Vref and the pulse signal Vpls are output is output from an output terminal of the AND gate 53c, and is input to the delay circuit 53d. The delay circuit 53d outputs the reset signal Reset=1 V when one microsecond elapses after the Fin_bit signal=1 V is input.

Since the delay time of the delay circuit 53d is one microsecond, the pulse widths of the extended reference signal Vref_bit and the extended pulse signal Vpls_bit become one microsecond or more. However, the pulse widths of the extended reference signal Vref_bit and the extended pulse signal Vpls_bit determined by the delay time of the delay circuit 53d are not limited to one microsecond. These pulse widths, that is, the delay time of the delay circuit 53d may be longer than the time from when the reference signal Vref and the pulse signal Vpls, and the extended reference signal Vref_bit and the extended pulse signal Vpls_bit are input to the long/short determination circuit 55 described later to when the values of Short_bit and Long_bit, which are outputs, are determined.

### Match Determination Circuit 54

Returning to FIG. 3, when the compensation input voltage Vin_bit=1 V is output from the input generation circuit 52, the match determination circuit 54 determines whether the timing at which the reference signal Vref is output from the reference signal circuit 40 matches the timing at which the pulse signal Vpls is output from the pulse generation circuit 20.

Specifically, when the time difference between the timing at which the reference signal Vref is output and the timing at which the pulse signal Vpls is output is equal to or less than one millisecond, which is a third predetermined value, the match determination circuit 54 determines that the timings at which the reference signal Vref and the pulse signal Vpls are output match, and outputs a match establishment signal Syn_bit=1 V and a match non-establishment signal ˜Syn_bit=0 V. In this regard, when the time difference between the timing at which the reference signal Vref is output and the timing at which the pulse signal Vpls is output is larger than one millisecond, the match determination circuit 54 determines that the timings at which the reference signal Vref and the pulse signal Vpls are output do not match, and outputs a match establishment signal Syn_bit=0 V and a match non-establishment signal ˜Syn_bit=1 V.

FIG. 7 is a diagram illustrating an internal configuration of the match determination circuit 54. The match determination circuit 54 includes a holding circuit 54a, a holding circuit 54b, an AND gate 54c, and an SR latch 54d.

When the reference signal Vref is input from the reference signal circuit 40, the holding circuit 54a outputs Vref_1 ms which is a signal obtained by extending the input reference signal Vref into a pulse having a width of one millisecond. An output terminal of the holding circuit 54a is connected to one input terminal of the AND gate 54c.

When the pulse signal Vpls is input from the pulse generation circuit 20, the holding circuit 54b outputs Vpls_1 ms which is a signal obtained by extending the input pulse signal Vpls into a pulse having a width of one millisecond. An output terminal of the holding circuit 54b is connected to the other input terminal of the AND gate 54c.

The widths of the pulses output from the holding circuits 54a and 54b are set to be equal to the third predetermined value described above. That is, in the present first embodiment, since the third predetermined value is one millisecond, the widths of the pulses output from the holding circuits 54a and 54b are also set to one millisecond. However, the third predetermined value is not limited to one millisecond, and can be set to an arbitrary time.

An output terminal of the AND gate 54c is connected to an S terminal of the SR latch 54d. The reset signal Reset is input to an R terminal of the SR latch 54d. A match establishment signal Syn_bit is output from a Q terminal of the SR latch 54d. A match non-establishment signal ˜Syn_bit is output from a ˜Q terminal of the SR latch 54d.

### Long/short Determination Circuit 55

Returning to FIG. 3, the long/short determination circuit 55 determines whether a waiting time from when the compensation input voltage Vin_bit=1 V is output by the input generation circuit 52 to when the pulse signal Vpls is output by the pulse generation circuit 20 is longer or shorter than a predetermined time until the reference signal Vref is output by the reference signal circuit 40.

Specifically, in a case where the waiting time until the pulse signal Vpls is output is longer than the predetermined time until the reference signal Vref is output, the long/short determination circuit 55 outputs Short_bit=0 V and Long_bit=1 V.

In this regard, when the waiting time until the pulse signal Vpls is output is shorter than the predetermined time until the reference signal Vref is output, the long/short determination circuit 55 outputs Short_bit=1 V and Long_bit=0 V.

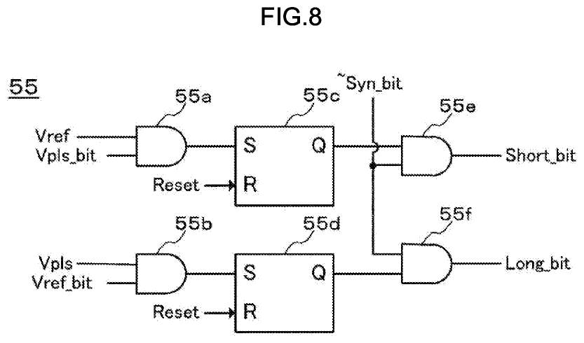

FIG. 8 is a diagram illustrating an internal configuration of the long/short determination circuit 55. The long/short determination circuit 55 includes an AND gate 55a, an AND gate 55b, an SR latch 55c, an SR latch 55d, an AND gate 55e, and an AND gate 55f.

The reference signal Vref is input from the reference signal circuit 40 to one input terminal of the AND gate 55a. The extended pulse signal Vpls_bit is input from the reset generation circuit 54 to the other input terminal of the AND gate 55a. An output terminal of the AND gate 55a is connected to an S terminal of the SR latch 55c.

The pulse signal Vpls is input from the pulse generation circuit 20 to one input terminal of the AND gate 55b. The expanded reference signal Vref_bit is input from the reset generation circuit 54 to the other input terminal of the AND gate 55b. An output terminal of the AND gate 55b is connected to an S terminal of the SR latch 55d.

The reset signal Reset is input to an R terminal of the SR latch 55c. A Q terminal of the SR latch 55c is connected to one input terminal of the AND gate 55e. The match non-establishment signal ˜Syn_bit is input from the match determination circuit 53 to the other input terminal of the AND gate 55e. A Short_bit signal is output from an output of the AND gate 55e.

The reset signal Reset is input to an R terminal of the SR latch 55d. An output terminal Q of the SR latch 55d is connected to one input terminal of the AND gate 55f. The match non-establishment signal ˜Syn_bit is input from the match determination circuit 53 to the other input terminal of the AND gate 55f. A Long_bit signal is output from an output of the AND gate 55f.

### Selection Signal Generation Circuit 56

Returning to FIG. 3, the selection signal generation circuit 56 generates and outputs five selection signals Vsw+2 to Vsw−2 based on the Short_bit signal and the Long_bit signal output from the long/short determination circuit. These five selection signals Vsw+2 to Vsw−2 are signals in which only one of them becomes 1 V and the others become 0 V based on the Short_bit signal and the Long_bit signal. As will be described later, the bulk voltage Vb of the transistor 11 included in the charging circuit 10 is controlled in five stages based on which of these five selection signals becomes 1 V.

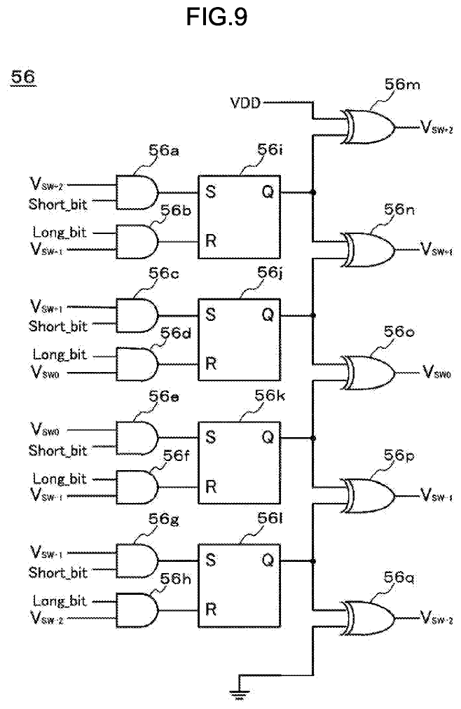

FIG. 9 is a diagram illustrating an internal configuration of the selection signal generation circuit 56. The selection signal generation circuit 56 includes eight AND gates 56a to 56h, four SR latches 56i to 56l, and five EXOR gates 56m to 56q.

A selection signal Vsw+2 and a Short_bit signal are input to two input terminals of the AND gate 56a. An output terminal of the AND gate 56a is connected to an S terminal of the SR latch 56i. A Long_bit signal and a selection signal Vsw+1 are input to two input terminals of the AND gate 56b. An output terminal of the AND gate 56b is connected to an R terminal of the SR latch 56i.

Similarly, a selection signal Vsw+1 and a Short_bit signal are input to two input terminals of the AND gate 56c. An output terminal of the AND gate 56c is connected to an S terminal of the SR latch 56j. A Long_bit signal and a selection signal Vsw0 are input to two input terminals of the AND gate 56d. An output terminal of the AND gate 56d is connected to an R terminal of the SR latch 56j.

Similarly, the selection signal Vsw0 and a Short_bit signal are input to two input terminals of the AND gate 56e. An output terminal of the AND gate 56e is connected to an S terminal of the SR latch 56k. A Long_bit signal and a selection signal Vsw−1 are input to two input terminals of the AND gate 56f. An output terminal of the AND gate 56f is connected to an R terminal of the SR latch 56k.

Similarly, the selection signal Vsw−1 and a Short_bit signal are input to two input terminals of the AND gate 56g. An output terminal of the AND gate 56g is connected to an S terminal of the SR latch 56l. The Long_bit signal and a selection signal Vsw−2 are input to two input terminals of the AND gate 56h. An output terminal of the AND gate 56h is connected to an R terminal of the SR latch 56l.

The power supply line VDD and a Q terminal of the SR latch 56i are connected to two input terminals of the EXOR gate 56m. The EXOR gate 56m outputs a selection signal Vsw+2.

Similarly, a Q terminal of the SR latch 56i and a Q terminal of the SR latch 56j are connected to two input terminals of the EXOR gate 56n. The EXOR gate 56n outputs a selection signal Vsw+1.

Similarly, a Q terminal of the SR latch 56j and a Q terminal of the SR latch 56k are connected to two input terminals of the EXOR gate 56o. The EXOR gate 56o outputs a selection signal Vsw0.

Similarly, a Q terminal of the SR latch 56k and a Q terminal of the SR latch 56l are connected to two input terminals of the EXOR gate 56p. The EXOR gate 56p outputs a selection signal Vsw−1.

Similarly, a Q terminal of the SR latch 56l and the ground GND are connected to two input terminals of the EXOR gate 56q. The EXOR gate 56q outputs a selection signal Vsw−2.

### Control Voltage Generation Circuit 57

Returning to FIG. 3, the control voltage generation circuit 57 generates and outputs a bulk control voltage Vctr_b based on the selection signals Vsw+2 to Vsw−2 output from the selection signal generation circuit 56. The bulk control voltage Vctr_b is applied to the bulk terminal of the transistor 11 included in the charging circuit 10.

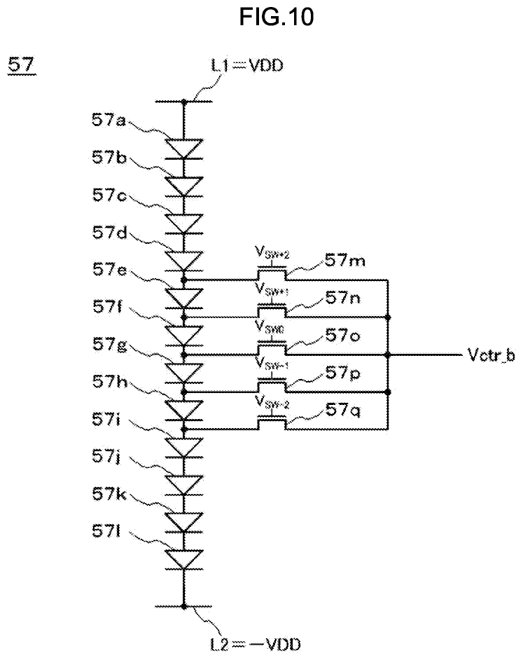

FIG. 10 is a diagram illustrating an internal configuration of the control voltage generation circuit 57. The control voltage generation circuit 57 includes twelve diodes 57a to 57l and five switches 57m to 57q.

The diodes 57a to 57l are connected in series in the forward direction between a first power supply line L1 connected to power supply line VDD and a second power supply L2 connected to a power supply line −VDD. Therefore, a voltage of δ=2 VDD/12 is applied to each diode. In the present first embodiment, since the voltage of the power supply line VDD is 1 V, δ=2/12≈0.17 V. The diodes 57a to 57l may be mounted by forming a PN junction on a semiconductor substrate, or may be mounted by diode-connected MOSFETs.

The switch 57m is turned on when the selection signal Vsw+2=1 V. The switch 57n is turned on when the selection signal Vsw+1=1 V. The switch 57o is turned on when the selection signal Vsw0=1 V. The switch 57p is turned on when the selection signal Vsw−1=1 V. The switch 57q is turned on when the selection signal Vsw−2=1 V.

When the selection signal Vsw+2=1 V and all the other selection signals are 0 V, a bulk control voltage Vctr_b=2 δ=0.34 V is output.

When the selection signal Vsw+1=1 V and all the other selection signals are 0 V, a bulk control voltage Vctr_b=δ=0.17 V is output.

When the selection signal Vsw0=1 V and all the other selection signals are 0 V, a bulk control voltage Vctr_b=0 V is output.

When the selection signal Vsw−1=1 V and all the other selection signals are 0 V, a bulk control voltage Vctr_b=−δ=−0.17 V is output.

When the selection signal Vsw−2=1 V and all the other selection signals are 0 V, a bulk control voltage Vctr_b=−2 δ=−0.34 V is output.

### Operation of Spiking Neuron Circuit System 100

Next, an operation of the spiking neuron circuit system 100 according to the present first embodiment will be described. First, a normal operation of the spiking neuron circuit system 100 will be described, and then a waiting time compensation operation of the spiking neuron circuit system 100, which is the main subject of the present disclosure, will be described.

### Normal Operation

A normal operation of the spiking neuron circuit system 100 according to the present first embodiment will be described. During the normal operation of the spiking neuron circuit system 100 of FIG. 1, the compensation input voltage Vin_bit=0 V and the switch control signal Vsw_bit=0 V. In an initial state, the capacitor 12 of the charging circuit 10 is not charged, and its charged voltage is 0 V.

Since the charged voltage of the capacitor 12 is 0 V, the voltage of the input node N1 of the pulse generation circuit 20 is also 0 V, and the output of the first-stage inverter 21 is 1 V. Therefore, the output of the second-stage inverter 22 is 0 V, the output of the third-stage inverter 23 is 1 V, the output of the last-stage inverter 24 is 0 V, and the voltage of the output node N2 is 0 V. Since the output node N2 is connected to the output terminal Tout, the voltage of the output terminal Tout is also 0 V.

A case where a DC voltage of 1 V is applied to the input terminal Tin from the external power supply (not shown) via the OR gate 60 in such an initial state will be considered. First, since the compensation input voltage Vin_bit=0 V, the power is not supplied from the control circuit 50 via the input terminal Tin. Since the switch control signal Vsw_bit=0 V, the DC power supplied from the external power supply (not shown) via the OR gate 60 is not supplied to the CR time constant circuit 30 but is supplied only to the charging circuit 10.

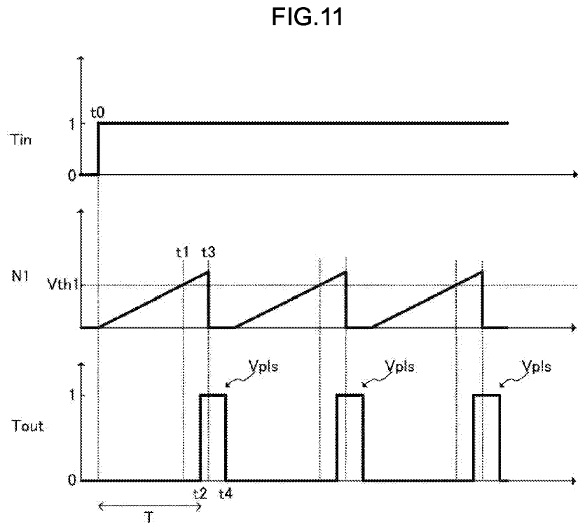

FIG. 11 is a timing chart illustrating an example of the normal operation of the spiking neuron circuit system 100. First, at time to, a DC voltage of 1 V is applied to the input terminal Tin from an external power supply (not shown) via the OR gate 60, so that the voltage of the input terminal Tin becomes 1 V.

At this time, an output current I, which is a subthreshold current, is output from the transistor 11 of the charging circuit 10. The capacitor 12 is charged by the output current I, and the charged voltage thereof rises. Since the charged voltage of the capacitor 12 is equal to the voltage of the input node N1 of the pulse generation circuit 20, the voltage of the input node N1 also rises.

At time t1, when the voltage of the input node N1 reaches a first predetermined value Vth1 that is a threshold at which the output of the first-stage inverter 21 is switched, the output of the first-stage inverter 21 changes from 1 V to 0 V. Due to this change, the output of the second-stage inverter 22 changes from 0 V to 1 V, the output of the third-stage inverter 23 changes from 1 V to 0 V, and the output of the last-stage inverter 24 changes from 0 V to 1 V, so that the voltage of the output node N2 rapidly rises from 0 V to 1 V after a certain time delay from when the voltage of the input node N1 reaches the first predetermined value Vth1. Since the output node N2 is connected to the output terminal Tout, the voltage of the output terminal Tout also rapidly rises from 0 V to 1 V.

At time t2, when the voltage of the output node N2 becomes 1 V, the transistor 27 of the pulse generation circuit 20 is turned on, and the voltage of the input node N1 becomes 0 V at time t3. As a result, the charge stored in the capacitor 12 of the charging circuit 10 flows from the input node N1 to the ground GND via the drain-source of the transistor 27, and the capacitor 12 is discharged.

At time 3, when the voltage of the input node N1 becomes 0 V, the output of the first-stage inverter 21 of the pulse generation circuit 20 changes from 0 V to 1 V. Due to this change, the output of the second-stage inverter 22 changes from 1 V to 0 V, the output of the third-stage inverter 23 changes from 0 V to 1 V, and the output of the last-stage inverter 24 changes from 1 V to 0 V, so that the voltage of the output node N2 rapidly drops from 1 V to 0 V after a certain time delay from when the voltage of the input node N1 becomes 0 V. Since the output node N2 is connected to the output terminal Tout, the voltage of the output terminal Tout also rapidly drops to 0 V at time t4.

Thereafter, while the voltage of the input terminal Tin is maintained at 1 V, the same operations as those from time t0 to time t4 are repeated. In the timing chart of FIG. 11, a time defined by T=t2-t0 corresponds to a predetermined waiting time in the spiking neuron circuit system 100.

As described above, when a DC voltage of 1 V is applied to the input terminal Tin from the external power supply (not shown) via the OR gate 60 during the normal operation of the spiking neuron circuit system 100 according to the present first embodiment, the pulse signal Vpls is output from the output terminal Tout after a predetermined waiting time T elapses. The pulse width of the pulse signal Vpls will be the width corresponding to a delay time formed by the four inverters 21 to 24.

### Waiting Time Compensation Operation

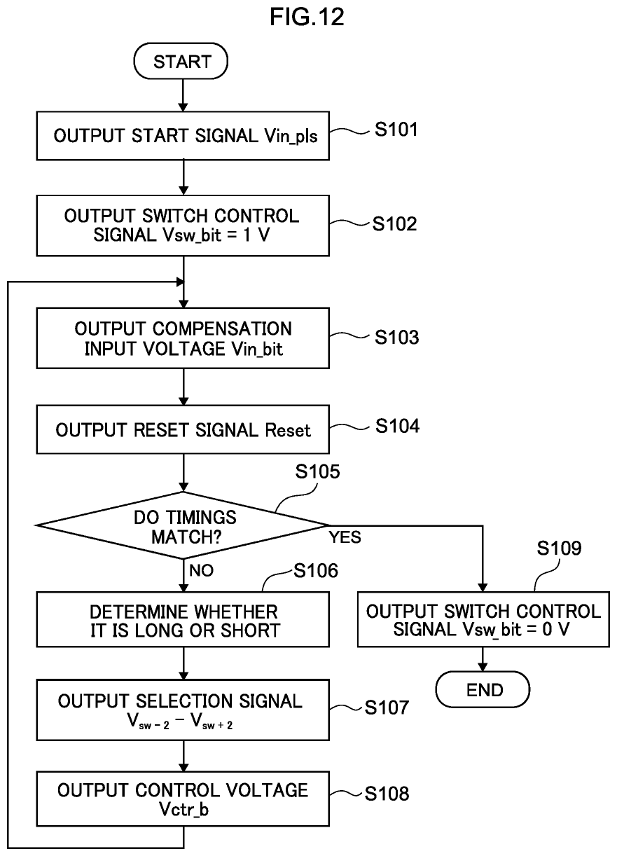

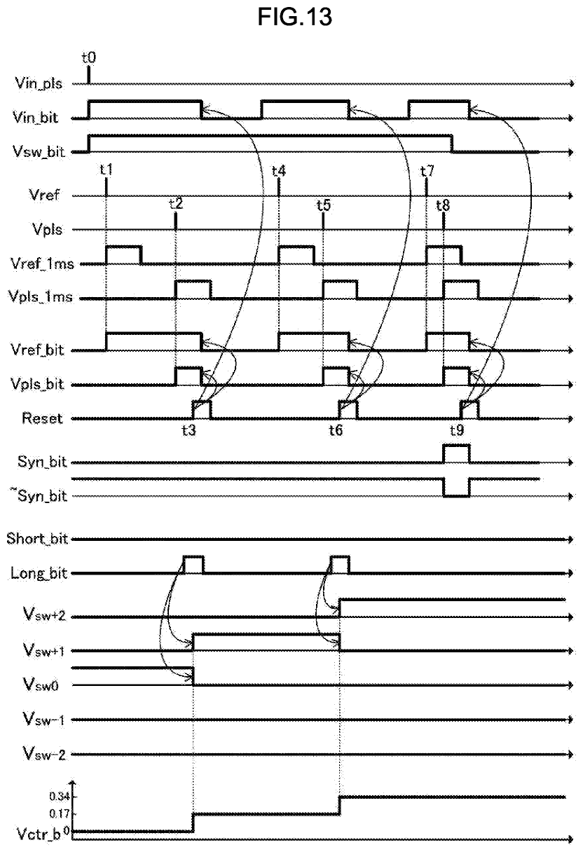

Next, a waiting time compensation operation of the spiking neuron circuit system 100 according to the present first embodiment will be described. FIG. 12 is a flowchart illustrating an operation of the control circuit 50 during the waiting time compensation operation of the spiking neuron circuit system 100. FIG. 13 is a timing chart illustrating an example of a waiting time compensation operation of the spiking neuron circuit system 100. In the following description, FIGS. 1 to 10 will also be referred.

In an initial state of the waiting time compensation operation of the spiking neuron circuit system 100 of FIG. 1, neither the capacitor 12 of the charging circuit 10 nor the capacitor C of the CR time constant circuit 30 is charged, and the charged voltage of each capacitor is 0 V. In the initial state, in the control circuit 50 of FIG. 3, a match establishment signal Syn_bit=0 V and a match non-establishment signal ˜Syn_bit=1 V, and a Reset signal=0 V. A switch control signal Vsw_bit=0 V, a compensation input voltage Vin_bit=0 V, and a bulk control voltage Vctr_b=0 V.

In step S101 of FIG. 12, the activation circuit 51 outputs a pulse-shaped start signal Vin_pls=1 V, and the start signal Vin_pls is input to the input generation circuit 52. As described above, the start signal Vin_pls is a signal for activating the control circuit 50 to start the waiting time compensation operation, and is output every one hour in the present first embodiment. In the timing chart of FIG. 13, the pulse-shaped start signal Vin_pls=1 V is output at time to.

In step S102, the input generation circuit 52 outputs a switch control signal Vsw_bit=1 V.

Specifically, in the input generation circuit 52 of FIG. 5, since the start signal Vin_pls=1 V and the match establishment signal Syn_bit=0 V, the switch control signal Vsw_bit=1 V is output from the Q terminal of the SR latch 52a.

In step S103, the input generation circuit 52 outputs a compensation input voltage Vin_bit=1 V.

Specifically, in the input generation circuit 52 of FIG. 5, since the start signal Vin_pls=1 V is input to the S terminal of the SR latch 52e via the OR gate 52d and the reset signal Reset=0 V, the compensation input voltage Vin_bit=1 V is output from the Q terminal of the SR latch 52e.

In the timing chart of FIG. 13, the switch control signal Vsw_bit=1 V and the compensation input voltage Vin_bit=1 V are output at substantially the same time as the pulse-shaped start signal Vin_pls=1 V is output.

As illustrated in FIG. 1, the compensation input voltage Vin_bit=1 V is applied to the input terminal Tin via the OR gate 60. Because of the switch control signal Vsw_bit=1 V, the DC power supplied from the input terminal Tin is supplied to both the charging circuit 10 and the CR time constant circuit 30.

At this time, the charging circuit 10 and the pulse generation circuit 20 operate in the same way as in the normal operation described above. That is, during the waiting time compensation operation, the compensation input voltage Vin_bit=1 V is applied to the input terminal Tin by the control circuit 50 instead of the external power supply (not shown). As a result, when the charged voltage of the capacitor 12 of the charging circuit 10 rises and the voltage of the input node N1 of the pulse generation circuit 20 reaches the first predetermined value, the operation of the pulse generation circuit 20 is started and the pulse signal Vpls is output from the output node N2. The pulse signal Vpls is input to the control circuit 50. In the timing chart of FIG. 13, the pulse signal Vpls is output at time t2.

The CR time constant circuit 30 and the reference signal circuit 40 also operate in almost the same way as the charging circuit 10 and the pulse generation circuit 20. That is, when the charged voltage of the capacitor C of the CR time constant circuit 30 rises and the voltage of the input node N3 of the reference signal circuit 40 reaches the second predetermined value, the operation of the reference signal circuit 40 is started and the reference signal Vref is output from the output node N4. The reference signal Vref is also input to the control circuit 50. In the timing chart of FIG. 13, the reference signal Vref is output at time t1.

In step S104, the reset generation circuit 53 outputs a reset signal Reset=1 V.

Specifically, the reset generation circuit 53 in FIG. 6 outputs the reset signal Reset=1 V when one microsecond elapses after both the reference signal Vref and the pulse signal Vpls are output. The reset generation circuit 53 outputs an extended reference signal Vref_bit whose output is started at the same timing as the reference signal Vref and an extended pulse signal Vpls_bit whose output is started at the same timing as the pulse signal Vpls.

In the timing chart of FIG. 13, after the reference signal Vref is output at time t1, when one microsecond elapses after the pulse signal Vpls is output at time t2, a Reset signal=1 V is output at time t3. When the reset signal Reset=1V rises, the extended reference signal Vref_bit, the extended pulse signal Vpls_bit, and the compensation input voltage Vin_bit fall.

In step S105, the match determination circuit 54 determines whether a timing at which the reference signal Vref is output matches a timing at which the pulse signal Vpls is output.

Specifically, in a case where a time difference between the timing at which the reference signal Vref is output and the timing at which the pulse signal Vpls is output is less than one millisecond, which is the third predetermined value, the match determination circuit 54 in FIG. 7 determines that the timings at which the reference signal Vref and the pulse signal Vpls are output match, and outputs a match establishment signal Syn_bit=1 V and a match non-establishment signal ˜Syn_bit=0 V. In other words, in a case where Vref_1 ms, which is a signal obtained by extending the reference signal Vref into a pulse having a width of one millisecond, and Vpls_1 ms, which is a signal obtained by extending the pulse signal Vpls into a pulse having a width of one millisecond overlap each other on a time axis, the match determination circuit 54 determines that the timings at which the reference signal Vref and the pulse signal Vpls are output match, and outputs the match establishment signal Syn_bit=1 V and the match non-establishment signal ˜Syn_bit=0 V.

In the timing chart of FIG. 13, the Vref_1 ms based on the reference signal Vref at time t1 and the Vpls_1 ms based on the pulse signal Vpls at time t2 do not overlap each other on the time axis, and output timings of the Vref_1 ms and the Vpls_1 ms do not match. Therefore, the match determination circuit 54 outputs a match establishment signal Syn_bit=0 V and a match non-establishment signal ˜Syn_bit=1 V.

In step S106, the long/short determination circuit 55 determines whether a waiting time from when the compensation input voltage Vin_bit=1 V is output to when the pulse signal Vpls is output is longer or shorter than a predetermined time until the reference signal Vref is output.

Specifically, the long/short determination circuit 55 in FIG. 8 outputs a Long_bit signal=1 V and a Short_bit signal=0 V in a case where the waiting time from when the compensation input voltage Vin_bit=1 V is output to when the pulse signal Vpls is output is longer than a predetermined time after the reference signal Vref is output.

In this regard, the long/short determination circuit 55 outputs a Long_bit signal=0 V and a Short_bit signal=1 V in a case where the waiting time from when the compensation input voltage Vin_bit=1 V is output to when the pulse signal Vpls is output is shorter than the predetermined time after the reference signal Vref is output.

In the timing chart of FIG. 13, a waiting time t2-t0 from when the compensation input voltage Vin_bit is output to when the pulse signal Vpls is output is longer than a predetermined time t1-t0 until the reference signal Vref is output. Therefore, the long/short determination circuit 55 outputs the Long_bit signal=1 V and the Short_bit signal=0 V.

In this case, in steps S107 to S108 described below, control is performed to increase the bulk voltage Vb of the transistor 11 of the charging circuit 10. As described above, the transistor 11 of the charging circuit 10 is an N-channel MOSFET. Therefore, as the bulk voltage Vb of the transistor 11 increases, the output current I of the transistor 11 increases, and the time until the charged voltage of the capacitor 12 reaches the first predetermined value is shortened. As a result, the waiting time until the pulse signal Vpls is output is shortened.

In step S107, the selection signal generation circuit 56 generates and outputs the selection signals Vsw+2 to Vsw−2 based on the states of the Long_bit signal, the Short_bit signal, and the current selection signal.

Specifically, in the initial state of the selection signal generation circuit 56 in FIG. 9, the Q terminal of the SR latch 56i=1 V, the Q terminal of the SR latch 56j=1 V, the Q terminal of the SR latch 56k=0 V, and the Q terminal of the SR latch 56l=0 V. Therefore, the initial outputs of the selection signal generation circuit 56 are Vsw+2=0 V, Vsw+1=0 V, Vsw0=1 V, Vsw−1=0 V, and Vsw−2=0 V. As a result, in the initial state, only the central switch 57o of the five switches 57m to 57q is turned on, and the bulk control voltage Vctr_b=0 V is output. That is, in the initial state, the voltage applied to the bulk terminal of the transistor 11 is 0 V.

In such an initial state, when the Long_bit signal=1 V and the Short_bit signal=0 V are input to the selection signal generation circuit 56, the selection signal generation circuit 56 outputs the selection signals Vsw+2=0 V, Vsw+1=1 V, Vsw0=0 V, Vsw−1=0 V, and Vsw−2=0 V. In the timing chart of FIG. 13, the selection signal Vsw0 is switched from 1 V to 0 V, and the selection signal Vsw+1 is switched from 0 V to 1 V. As a result, among the five switches 57m to 57q, only the switch 57n one stage above from the center is turned on.

In step S108, the control voltage generation circuit 57 generates and outputs the bulk control voltage Vctr_b based on the selection signals Vsw+2 to Vsw−2.

Specifically, in the control voltage generation circuit 57 of FIG. 10, when the selection signal Vsw+1=1 V and all the other selection signals are 0 V, 0 V+δ=0.17 V is output as the bulk control voltage Vctr_b. In the timing chart of FIG. 13, the bulk control voltage Vctr_b changes from 0 V to 0.17 V.

The bulk control voltage Vctr_b is applied to the bulk terminal of the transistor 11 of the charging circuit 10. As a result, the bulk voltage Vb of the transistor 11 rises from 0 V to 0.17 V, the output current I of the transistor 11 increases, and the time until the charged voltage of the capacitor 12 reaches the first predetermined value is shortened. As a result, the waiting time from when the input voltage is applied to when the pulse signal Vpls is output is shortened.

Thereafter, the operations from steps S103 to S108 described above are repeated until the timing at which the reference signal Vref is output matches the timing at which the pulse signal Vpls is output and step S105=YES is satisfied.

Specifically, in the timing chart of FIG. 13, the timing at which the reference signal Vref is output at time t4 and the timing at which the pulse signal Vpls is output at time t5 do not match yet. Therefore, in step S107, the selection signal generation circuit 56 generates and outputs the selection signals Vsw+2=1 V, Vsw+1=0, Vsw0=0 V, Vsw−1=0 V, and Vsw−2=0 V. At this time, 0 V+2 δ=0.34 V is output from the control voltage generation circuit 57 as the bulk control voltage Vctr_b.

Next, in the timing chart of FIG. 13, the timing at which the reference signal Vref is output at time t7 matches the timing at which the pulse signal Vpls is output at time t8, and step S105=YES is satisfied. At this time, the match determination circuit 54 outputs a match establishment signal Syn_bit=1 V and a match non-establishment signal ˜Syn_bit=0 V.

In step S109, the input generation circuit 52 outputs a switch control signal Vsw_bit=0 V. As a result, the output of the AND gate 31 of the CR time constant circuit 30 becomes 0 V, and the power supply to the resistor R and the capacitor C is cut off. As described above, the operation of the flowchart of FIG. 12 ends, and the waiting time compensation operation of the spiking neuron circuit system 100 is completed. That is, the so-called calibration operation is completed.

When the match determination circuit 54 outputs the match establishment signal Syn_bit=1 V and the match non-establishment signal ˜Syn_bit=0 V immediately before the completion of the above-described waiting time compensation operation, the output of the long/short determination circuit 55 in FIG. 8 becomes the Long_bit signal=0 V and the Short_bit signal=0 V. At this time, the outputs of the AND gates 56a to 56l of the selection signal generation circuit 56 of FIG. 9 are all 0 V, and each of the SR latches 56m to 56q maintains an output state Q when the match is established. This output state is also maintained during the normal operation after completion of the waiting time compensation operation.

In other words, even after the completion of the waiting time compensation operation, each of the SR latches 56m to 56q stores, as an internal state Q, information for generating the selection signals Vsw+2 to Vsw−2 when the match is established. Therefore, the control voltage generation circuit 57 of FIG. 10 can continue to output the bulk control voltage Vctr_b when the match is established based on the selection signals Vsw+2 to Vsw−2 output from the selection signal generation circuit 56 even during the normal operation after the completion of the waiting time compensation operation.

As described above, the spiking neuron circuit system 100 according to the present first embodiment includes the control circuit 50 that controls the output current I of the transistor 11 by controlling the bulk voltage Vb of the transistor 11 included in the charging circuit 10. With such a feature, the spiking neuron circuit system 100 can determine a waiting time from when the input voltage is applied by the external power supply (not shown) during the normal operation to when the pulse signal Vpls is output with high accuracy.

In particular, the variation with respect to the temperature change of a predetermined time from when the compensation input voltage Vin_bit is applied to when the reference signal Vref is output is smaller than the variation with respect to the temperature change of the waiting time from when the compensation input voltage Vin_bit is applied to when the pulse signal Vpls is output. Therefore, even when a temperature environment changes during the operation of the spiking neuron circuit system 100, the variation due to the temperature change of the waiting time can be compensated by performing the waiting time compensation operation at predetermined time intervals.

The resistor R and the capacitor C included in the CR time constant circuit 30 of the spiking neuron circuit system 100 are configured by individual elements externally attached to the semiconductor substrate. On the other hand, the charging circuit 10 is mounted on the semiconductor substrate. Therefore, the accuracy of the predetermined time from when the compensation input voltage Vin_bit is applied to when the reference signal Vref is output is higher than the accuracy of the waiting time from when the compensation input voltage Vin_bit is applied to when the pulse signal Vpls is output. The spiking neuron circuit system 100 can determine the waiting time with high accuracy by compensating for the waiting time to match the highly accurate predetermined time defined by the CR time constant circuit 30.

Note that, the resistor R and the capacitor C configured by the individual elements have higher accuracy than a transistor and a capacitor mounted on a semiconductor substrate, but have large power consumption. For example, while the power consumption of the charging circuit 10 in which a charging time is set to 0.15 seconds is about 10⁻¹² W, the power consumption of the CR time constant circuit 30 in which a charging time is set to the same 0.15 seconds is about 10⁻⁹ W.

To address this power consumption problem, the spiking neuron circuit system 100 includes an AND gate 31 that functions as a switch that controls the power supply to the resistor R and the capacitor C. The AND gate 31 allows the power supply to the resistor R and the capacitor C only when the waiting time compensation operation is performed, and cuts off the power supply during the normal operation other than that. As a result, the spiking neuron circuit system 100 can achieve both high-accuracy waiting time and low power consumption.

In the first embodiment, the number of selection signals generated by the selection signal generation circuit 56 of the control circuit 50 is five from Vsw+2 to Vsw−2, and correspondingly, the change in the bulk control voltage Vctr_b output from the control voltage generation circuit 57 is also five stages. However, the number of selection signals is not limited to five, and the change of the bulk control voltage Vctr_b corresponding to the selection signals is not limited to five stages.

The bulk control voltage Vctr_b may be further changed in multiple stages by generating more selection signals by increasing the number of elements configuring the selection signal generation circuit 56 and correspondingly increasing the number of switches of the control voltage generation circuit 57. The range in which the bulk control voltage Vctr_b changes is not limited to the range of 0 V−2 δ=−0.34 V to 0 V+2 δ=0.34 V. In the case of the N-channel MOSFET, when the power supply voltage of the spiking neuron circuit system 100 is VDD, for example, the bulk control voltage Vctr_b can be changed in a range of −VDD to 0.4 VDD.

In the above-described first embodiment, the SR latches 56i to 56l of the selection signal generation circuit 56 store, as an internal state Q, information for generating the selection signals Vsw+2 to Vsw−2 when the match is established. The control voltage generation circuit 57 outputs the bulk control voltage Vctr_b based on the selection signals Vsw+2 to Vsw−2 output from the selection signal generation circuit 56 during the normal operation after completion of the waiting time compensation operation. Alternatively, a circuit that stores the bulk control voltage Vctr_b itself may be separately provided, and the bulk control voltage Vctr_b may be output with reference to the circuit during the normal operation. Alternatively, a circuit that stores the selection signals Vsw+2 to Vsw−2 when the match is established may be separately provided.

### Second Embodiment

### Spiking Neuron Circuit System 200

Next, a spiking neuron circuit system 200 according to a second embodiment of the present disclosure will be described. In the following description, the same or similar components as those in the first embodiment are denoted by the same reference numerals, and detailed description thereof is omitted.

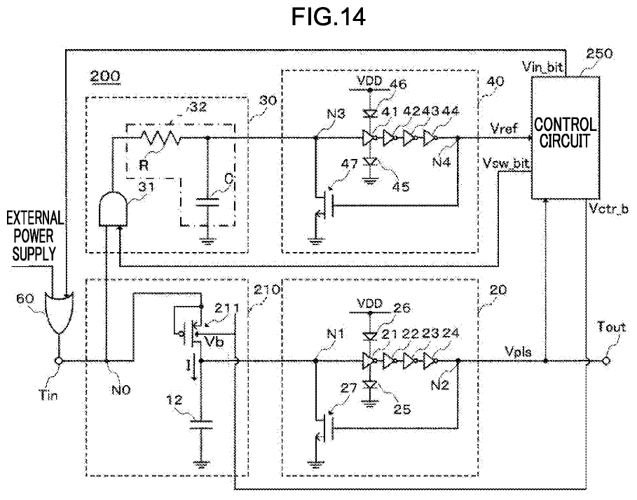

FIG. 14 is a diagram illustrating a configuration of a spiking neuron circuit system 200 according to a second embodiment of the present disclosure. In the spiking neuron circuit system 200, the transistor 11 which is an N-channel MOSFET included in the charging circuit 10 of the spiking neuron circuit system 100 according to the first embodiment is replaced with a transistor 211 which is a P-channel MOSFET.

When the spiking neuron circuit system 200 is compared with the spiking neuron circuit system 100 according to the first embodiment, only a charging circuit 210 and a control circuit 250 are different. Therefore, the charging circuit 210 and the control circuit 250 will be described in detail.

### Charging Circuit 210

The charging circuit 210 includes a transistor 211 which is a P-channel MOSFET and a capacitor 12. A source terminal of the transistor 211 is connected to an input node N0 of the charging circuit 210. A drain terminal of the transistor 211 is connected to one terminal of the capacitor 12 and an input node N1 of the pulse generation circuit 20. A gate terminal and a source terminal of the transistor 211 are short-circuited. When an input voltage is applied to the input terminal Tin from an external power supply (not shown) or the control circuit 250 via the OR gate 60, the charging circuit 210 starts charging of the capacitor 12 by the output current I that is a subthreshold current of the transistor 211.

### Control Circuit 250

When the control circuit 250 is compared with the control circuit 50 of the first embodiment, only a selection signal generation circuit 256 and a control voltage generation circuit 257 are different, and the other components are the same. Therefore, the selection signal generation circuit 256 and the control voltage generation circuit 257 will be described in detail.

### Selection Signal Generation Circuit 256

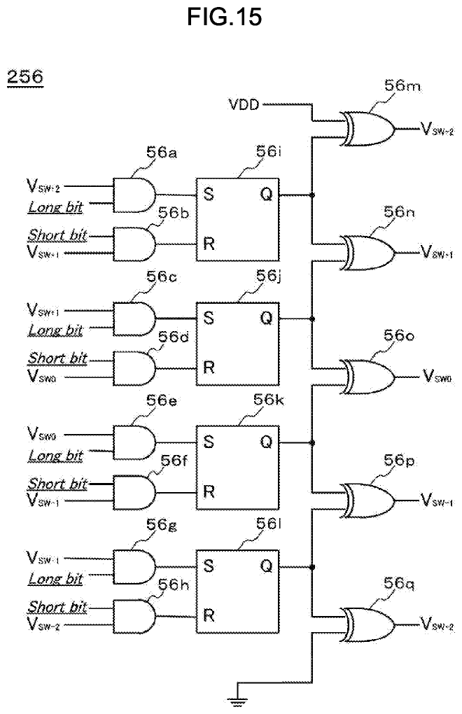

FIG. 15 is a diagram illustrating an internal configuration of the selection signal generation circuit 256. Similarly to the selection signal generation circuit 56 of the first embodiment, the selection signal generation circuit 256 includes eight AND gates 56a to 56h, four SR latches 56i to 56l, and five EXOR gates 56m to 56q.

When the selection signal generation circuit 256 is compared with the selection signal generation circuit 56 of the first embodiment, a Long_bit signal and a Short_bit signal input to each of the AND gates 56a to 56h are exchanged. In FIG. 15, differences from the first embodiment are highlighted in underlined italics.

In the selection signal generation circuit 256, the Long_bit signal and the Short_bit signal are exchanged for the following reason. That is, in the N-channel MOSFET, increasing the bulk voltage Vb increases the output current and shortens the waiting time, and decreasing the bulk voltage Vb decreases the output current and lengthens the waiting time. On the other hand, in the P-channel MOSFET, increasing the bulk voltage Vb decreases the output current and lengthens the waiting time, and decreasing the bulk voltage Vb increases the output current and shortens the waiting time.

In other words, in the N-channel MOSFET, it is necessary to “increase” the bulk voltage Vb in order to shorten the waiting time, and it is necessary to “decrease” the bulk voltage Vb in order to lengthen the waiting time. On the other hand, in the P-channel MOSFET, it is necessary to “decrease” the bulk voltage Vb in order to shorten the waiting time, and it is necessary to “increase” the bulk voltage Vb in order to lengthen the waiting time. Thus, both of them have a symmetrical relationship.

Therefore, the selection signal generation circuit 256 for the P-channel MOSFET can be configured by exchanging the Long_bit signal and the Short_bit signal input to each of the AND gates 56a to 56h of the selection signal generation circuit 56 of the first embodiment designed for the N-channel MOSFET.

When the Long_bit signal=1 V and the Short_bit signal=0 V, the selection signal generation circuit 256 generates the selection signals Vsw+2 to Vsw−2 that decrease the bulk voltage Vb by one stage in order to shorten the waiting time, and when the Long_bit signal=0 V and the Short_bit signal 1 V, the selection signal generation circuit generates the selection signals Vsw+2 to Vsw−2 that increase the bulk voltage Vb by one stage in order to lengthen the waiting time.

### Control Voltage Generation Circuit 257

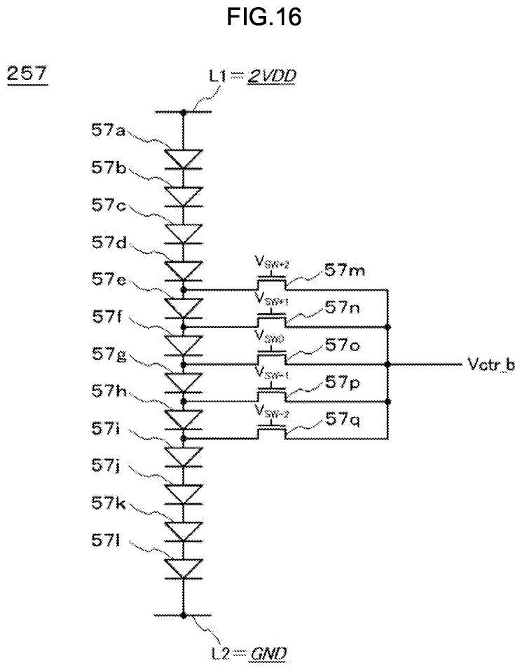

FIG. 16 is a diagram illustrating an internal configuration of the control voltage generation circuit 257. Similarly to the control voltage generation circuit 57 of the first embodiment, the control voltage generation circuit 257 includes twelve diodes 57a to 57l and five switches 57m to 57q.

When the control voltage generation circuit 257 is compared with the control voltage generation circuit 57 of the first embodiment, the connection destinations of the first power supply line L1 and the second power supply line L2 at both ends of the diodes connected in series in the forward direction are different. Specifically, in the first embodiment, the first power supply line L1 is connected to the power supply line VDD, and the second power supply line L2 is connected to the power supply line-VDD. On the other hand, in the control voltage generation circuit 257, the first power supply line L1 is connected to a power supply line 2VDD, and the second power supply line L2 is connected to a ground GND. In FIG. 16, differences from the first embodiment are highlighted in underlined italics.

In the N-channel MOSFET, the bulk voltage Vb can be changed, for example, in a range of −VDD to 0.4 VDD, when the power supply voltage is VDD. Therefore, in the first embodiment, the bulk control voltage Vctr_b is generated in the range of 0 V−2 δ=−0.34 V to 0 V+2 δ=0.34 V, with 0 V as a center. Here, δ=2 VDD/12≈0.17 V.

On the other hand, in the P-channel MOSFET, the bulk voltage Vb can be changed in a range of, for example, 0.6 VDD to 2 VDD, when the power supply voltage is VDD. Therefore, the control voltage generation circuit 257 generates the bulk control voltage Vctr_b in a range of 1 V−2 δ=0.66 V to 1 V+2 δ=1.34 V, with 1 V as a center. Here, δ=2 VDD/12≈0.17 V.

### Waiting Time Compensation Operation of Spiking Neuron Circuit System 200

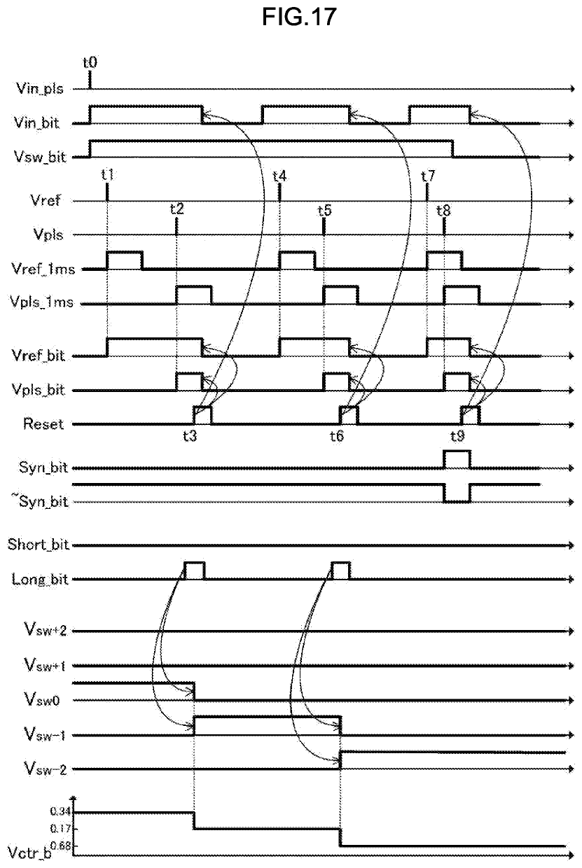

FIG. 17 is a timing chart illustrating an example of a waiting time compensation operation of the spiking neuron circuit system 200. In the timing chart of FIG. 17, since the waiting time from when the compensation input voltage Vin_bit is applied to when the pulse signal Vpls is output is longer than the predetermined time until the reference signal Vref is output, control for shortening the waiting time is performed. Specifically, in order to decrease the bulk voltage Vb of the transistor 211 of the charging circuit 210, control is performed to decrease the bulk control voltage Vctr_b in stages.

As described above, the spiking neuron circuit system 200 according to the present second embodiment includes the control circuit 250 that controls the output current I of the transistor 211 by controlling the bulk voltage Vb of the transistor 211, which is a P-channel MOSFET included in the charging circuit 210. Even with such a configuration, the waiting time from when the input voltage is applied by the external power supply (not shown) to when the pulse signal Vpls is output during the normal operation can be determined with high accuracy.

Note that, the magnitude of the subthreshold current is different between the N-channel MOSFET and the P-channel MOSFET. Therefore, it is preferable to select the N-channel type or the P-channel type according to the range of the subthreshold current suitable for obtaining a desired waiting time. When such a constraint does not exist, a P-channel type in which a bulk terminal is isolated from a semiconductor substrate reduces the area required for mounting. In the case of the N-channel type, it is necessary to use an NBL-NMOS in order to isolate a bulk terminal from a semiconductor substrate, and an area required for mounting increases.

### Third Embodiment

### Spiking Neuron Circuit System 300

Next, a spiking neuron circuit system 300 according to a third embodiment of the present disclosure will be described.

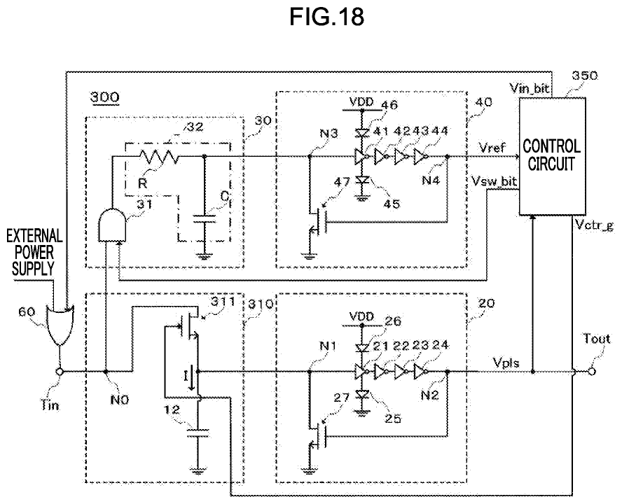

FIG. 18 is a diagram illustrating a configuration of a spiking neuron circuit system 300 according to a third embodiment of the present disclosure. In the spiking neuron circuit systems according to the first and second embodiments, the waiting time is compensated by controlling the bulk voltage Vb of the MOSFET included in the charging circuit. On the other hand, in the spiking neuron circuit system 300 according to the present third embodiment, a waiting time is compensated by controlling a gate voltage Vg of the N-channel MOSFET.

When the spiking neuron circuit system 300 is compared with the spiking neuron circuit system 100 according to the first embodiment, only a charging circuit 310 and a control circuit 350 are different. Therefore, the charging circuit 310 and the control circuit 350 will be described in detail.

### Charging Circuit 310

The charging circuit 310 includes a transistor 311 which is an N-channel MOSFET and a capacitor 12. A drain terminal of the transistor 311 is connected to an input node N0 of the charging circuit 310. A source terminal of the transistor 311 is connected to one terminal of the capacitor 12 and an input node N1 of the pulse generation circuit 20. A gate terminal and a source terminal of the transistor 311 are not short-circuited.

### Control Circuit 350

When the control circuit 350 is compared with the control circuit 50 of the first embodiment, only a control voltage generation circuit 357 is different, and the other components are the same. Therefore, the control voltage generation circuit 357 will be described in detail.

The configuration of the selection signal generation circuit 56 of the present third embodiment is the same as that of the first embodiment, for the following reasons. That is, in the case of the N-channel MOSFET, the output current increases regardless of whether the bulk voltage Vb is increased or the gate voltage Vg is increased, and the output current decreases regardless of whether the bulk voltage Vb is decreased or the gate voltage Vg is decreased. Therefore, when the selection signal generation circuit 56 generates the selection signals Vsw+2 to Vsw−2, it is not necessary to distinguish whether the control target is the bulk voltage Vb or the gate voltage Vg.

### Control Voltage Generation Circuit 357

The control voltage generation circuit 357 generates and outputs a gate control voltage Vctr_g based on the selection signals Vsw+2 to Vsw−2 output from the selection signal generation circuit 56. The gate control voltage Vctr_g is applied to the gate terminal of the transistor 311 included in the charging circuit 310.

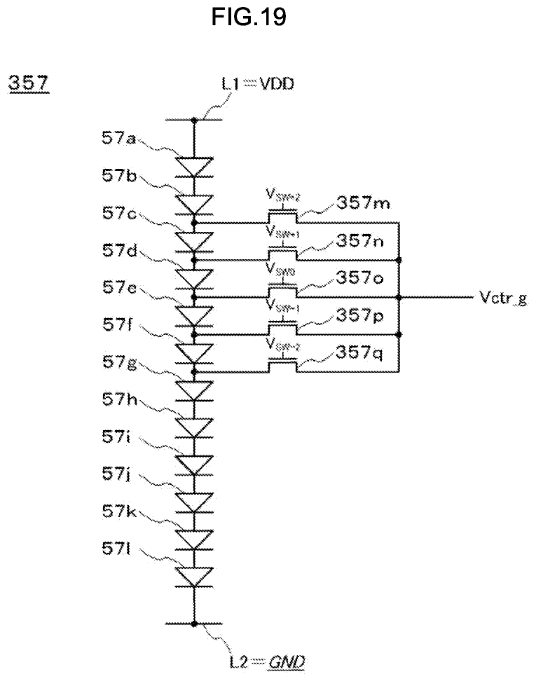

FIG. 19 is a diagram illustrating an internal configuration of the control voltage generation circuit 357. The control voltage generation circuit 357 includes twelve diodes 57a to 57l and five switches 357m to 357q. A first power supply line L1 is connected to a power supply line VDD, and a second power supply line L2 is connected to a ground GND.

In the N-channel MOSFET, the gate voltage Vg can be changed in a range of, for example, 0 to VDD, when the power supply voltage is VDD. Therefore, the control voltage generation circuit 357 generates the gate control voltage Vctr_g in a range of 0.67 V−2 δ=0.5 V to 0.67 V+2 δ=0.83 V, with 0.67 V as a center. Here, δ=VDD/12≈0.083 V.

As described above, the spiking neuron circuit system 300 according to the present third embodiment includes the control circuit 350 that controls the output current I of the transistor 311 by controlling the gate voltage Vg of the transistor 311, which is an N-channel MOSFET included in the charging circuit 310. Even with such a configuration, a waiting time from when an input voltage is applied by an external power supply (not shown) to when the pulse signal Vpls is output during a normal operation can be determined with high accuracy. Note that, since the bulk voltage Vb has a smaller influence on the channel current of the MOSFET than the gate voltage Vg, the waiting time can be more finely compensated by controlling the bulk voltage Vb. By combining the present third embodiment and the first embodiment, both the bulk voltage Vb and the gate voltage Vg of the N-channel MOSFET included in the charging circuit may be controlled.

### Fourth Embodiment

### Spiking Neuron Circuit System 400

Next, a spiking neuron circuit system 400 according to a fourth embodiment of the present disclosure will be described.

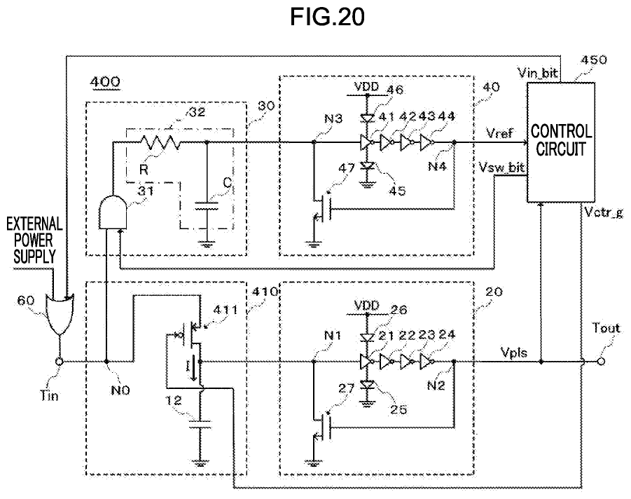

FIG. 20 is a diagram illustrating a configuration of a spiking neuron circuit system 400 according to a fourth embodiment of the present disclosure. In the spiking neuron circuit system 400 according to the present fourth embodiment, a waiting time is compensated by controlling a gate voltage Vg of a P-channel MOSFET.

When the spiking neuron circuit system 400 is compared with the spiking neuron circuit system 200 according to the second embodiment, only a charging circuit 410 and a control circuit 450 are different. Therefore, the charging circuit 410 and the control circuit 450 will be described in detail.

### Charging Circuit 410

The charging circuit 410 includes a transistor 411 which is a P-channel MOSFET and a capacitor 12. A source terminal of the transistor 411 is connected to an input node N0 of the charging circuit 410. A drain terminal of the transistor 411 is connected to one terminal of the capacitor 12 and an input node N1 of the pulse generation circuit 20. A gate terminal and a source terminal of the transistor 411 are not short-circuited.

### Control Circuit 450

When the control circuit 450 is compared with the control circuit 250 of the second embodiment, only a control voltage generation circuit 457 is different, and the other components are the same. Therefore, the control voltage generation circuit 457 will be described in detail.

The configuration of the selection signal generation circuit 256 of the present fourth embodiment is the same as that of the second embodiment, for the following reasons. That is, in the case of the P-channel MOSFET, the output current decreases regardless of whether the bulk voltage Vb is increased or the gate voltage Vg is increased, and the output current increases regardless of whether the bulk voltage Vb is decreased or the gate voltage Vg is decreased. Therefore, when the selection signal generation circuit 256 generates the selection signals Vsw+2 to Vsw−2, it is not necessary to distinguish whether the control target is the bulk voltage Vb or the gate voltage Vg.

### Control Voltage Generation Circuit 457

The control voltage generation circuit 457 generates and outputs a gate control voltage Vctr_g based on the selection signals Vsw+2 to Vsw−2 output from the selection signal generation circuit 256. The gate control voltage Vctr_g is applied to the gate terminal of the transistor 411 included in the charging circuit 410.

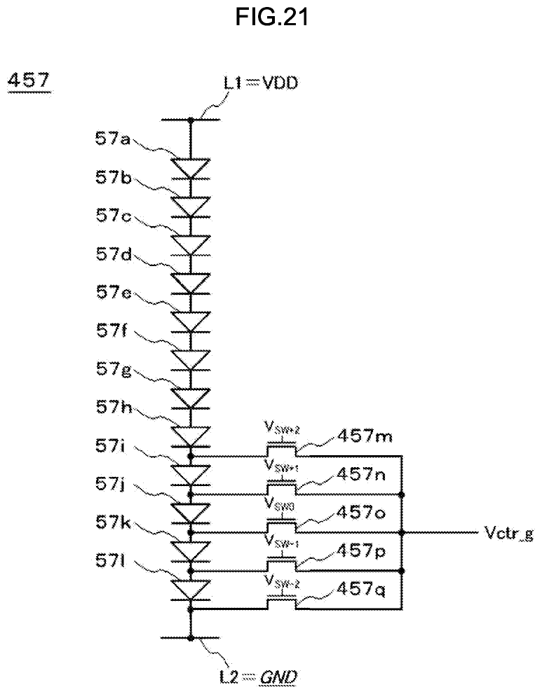

FIG. 21 is a diagram illustrating an internal configuration of the control voltage generation circuit 457. The control voltage generation circuit 457 includes twelve diodes 57a to 57l and five switches 457m to 457q. A first power supply line L1 is connected to a power supply line VDD, and a second power supply line L2 is connected to a ground GND.

In the P-channel MOSFET, the gate voltage Vg can be changed in a range of, for example, 0 to VDD, when the power supply voltage is VDD. Therefore, the control voltage generation circuit 457 generates the gate control voltage Vctr_g in a range of 0.17 V−2 δ=0 V to 0.17 V+2 δ=0.33 V, with 0.17 V as a center. Here, δ=VDD/12≈0.083 V.

As described above, the spiking neuron circuit system 400 according to the present fourth embodiment includes the control circuit 450 that controls the output current I of the transistor 411 by controlling the gate voltage Vg of the transistor 411, which is a P-channel MOSFET included in the charging circuit 410. Even with such a configuration, a waiting time from when an input voltage is applied by an external power supply (not shown) to when a pulse signal Vpls is output during a normal operation can be determined with high accuracy. Note that, since the bulk voltage Vb has a smaller influence on the channel current of the MOSFET than the gate voltage Vg, the waiting time can be more finely compensated by controlling the bulk voltage Vb. By combining the present fourth embodiment and the second embodiment, both the bulk voltage Vb and the gate voltage Vg of the P-channel MOSFET included in the charging circuit may be controlled.

### Fifth Embodiment

### Modification of Charging Circuit

In a fifth embodiment of the present disclosure, various modifications of a charging circuit of a spiking neuron circuit system will be described.

### First Modification

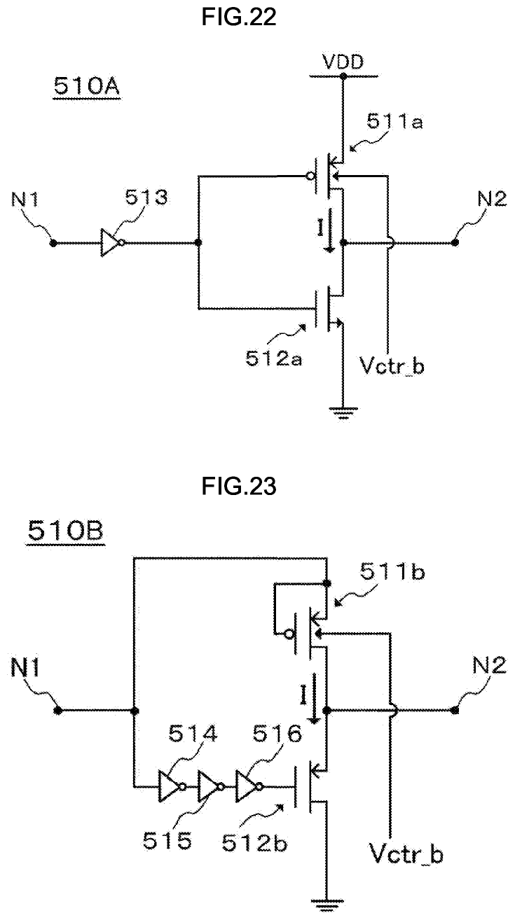

FIG. 22 is a diagram illustrating a configuration of a charging circuit 510A according to a first modification of the present fifth embodiment. The charging circuit 510A includes a transistor 511a which is a P-channel MOSFET, a transistor 512a which is an N-channel MOSFET, and an inverter 513.

When an input node N1 of the charging circuit 510A is 0 V, the inverter 513 outputs 1 V. At this time, the transistor 511a is turned off, and the transistor 512a is turned on. Therefore, a node N2 is 0 V.

When an input voltage of 1 V is applied to the input node N1 of the charging circuit 510A, the output of the inverter 513 becomes 0 V. At this time, the transistor 511a is turned on, and an output current I flows. In this regard, the transistor 512a is turned off, and a current does not flow between the drain and the source. In this state, a drain-source parasitic capacitance Cds of the transistor 512a functions as a capacitance component in the present disclosure. As a result, the output current I of the transistor 511a is charged in the parasitic capacitance Cds of the transistor 512a. By charging by using the on-current of the transistor 511a which is a P-channel MOSFET, a much shorter waiting time can be obtained than when charging by using the above-described subthreshold current.

### Second Modification

FIG. 23 is a diagram illustrating a configuration of a charging circuit 510B according to a second modification of the present fifth embodiment. The charging circuit 510B includes a transistor 511b which is a P-channel MOSFET, a transistor 512b which is an N-channel MOSFET, and three inverters 514 to 516 connected in multiple stages. Since a gate terminal and a source terminal of the transistor 511b are short-circuited, a subthreshold current I flows.

When an input node N1 of the charging circuit 510B is 0 V, the inverter 516 outputs 1 V, and the transistor 512b is on. Therefore, a node N2 is 0 V.

When an input voltage of 1 V is applied to the input node N1 of the charging circuit 510B, the output of the inverter 516 becomes 0 V after a certain delay time. At this time, the transistor 512b is turned off, and a current does not flow between the drain and the source. In this state, a drain-source parasitic capacitance Cds of the transistor 512b functions as a capacitance component in the present disclosure. As a result, the subthreshold current I of the transistor 511b is charged in the parasitic capacitance Cds of the transistor 512b.

### Third Modification

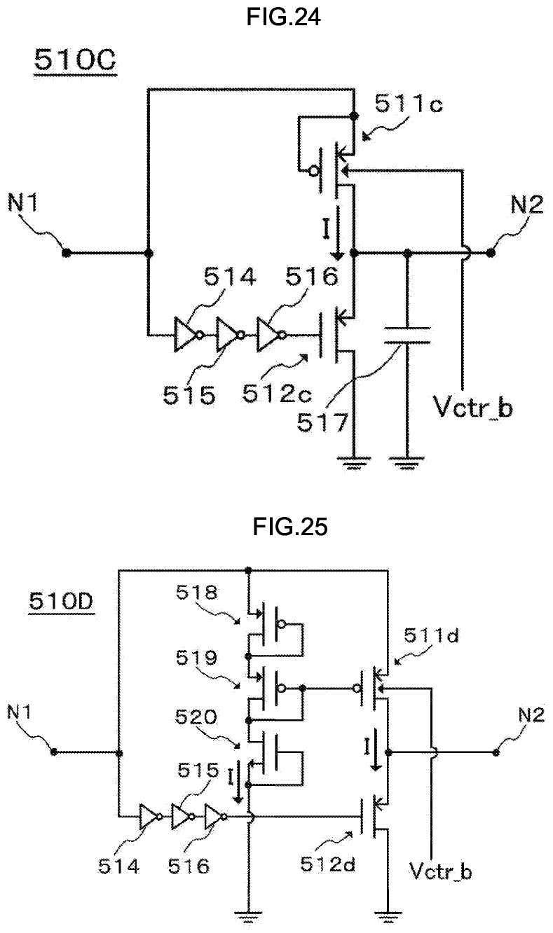

FIG. 24 is a diagram illustrating a configuration of a charging circuit 510C according to a third modification of the present fifth embodiment. The charging circuit 510C includes a transistor 511c which is a P-channel MOSFET, a transistor 512c which is an N-channel MOSFET, three inverters 514 to 516 connected in multiple stages, and a capacitor 517 connected in parallel with the transistor 512c. Since a gate terminal and a source terminal of the transistor 511c are short-circuited, a subthreshold current I flows.

When an input node N1 of the charging circuit 510C is 0 V, the inverter 516 outputs 1 V, and the transistor 512c is on. Therefore, a node N2 is 0 V.

When an input voltage of 1 V is applied to the input node N1 of the charging circuit 510C, the output of the inverter 516 becomes 0 V after a certain delay time. At this time, the transistor 512c is turned off, and a current does not flow between the drain and the source. In this state, a drain-source parasitic capacitance Cds of the transistor 512c and the capacitor 517 function as capacitance components in the present disclosure. As a result, the subthreshold current I of the transistor 511c is charged in the parasitic capacitance Cds of the transistor 512c and the capacitor 517. At this time, since the capacitor 517 is added, a longer waiting time can be generated.

### Fourth Modification

FIG. 25 is a diagram illustrating a configuration of a charging circuit 510D according to a fourth modification of the present fifth embodiment. The charging circuit 510D includes a transistor 511d which is a P-channel MOSFET, a transistor 512d which is an N-channel MOSFET, three inverters 514 to 516 connected in multiple stages, and transistors 518 to 520 that are three cascade-connected MOSFETs.

Since a gate terminal and a source terminal of the transistor 520 are short-circuited, a subthreshold current I flows. The subthreshold current I is amplified and becomes an output current I of the transistor 511d.

When an input node N1 of the charging circuit 510D is 0 V, the inverter 516 outputs 1 V, and the transistor 512d is on. Therefore, a node N2 is 0 V.

When an input voltage of 1 V is applied to the input node N1 of the charging circuit 510D, the output of the inverter 516 becomes 0 V after a certain delay time. At this time, the transistor 512d is turned off, and a current does not flow between the drain and the source. In this state, a drain-source parasitic capacitance Cds of the transistor 512d functions as a capacitance component in the present disclosure. As a result, the output current I of the transistor 511d is charged in the parasitic capacitance Cds of the transistor 512d.

### Sixth Embodiment

### Modification of Pulse Generation Circuit

In a sixth embodiment of the present disclosure, various modifications of a pulse generation circuit of a spiking neuron circuit system will be described.

### First Modification

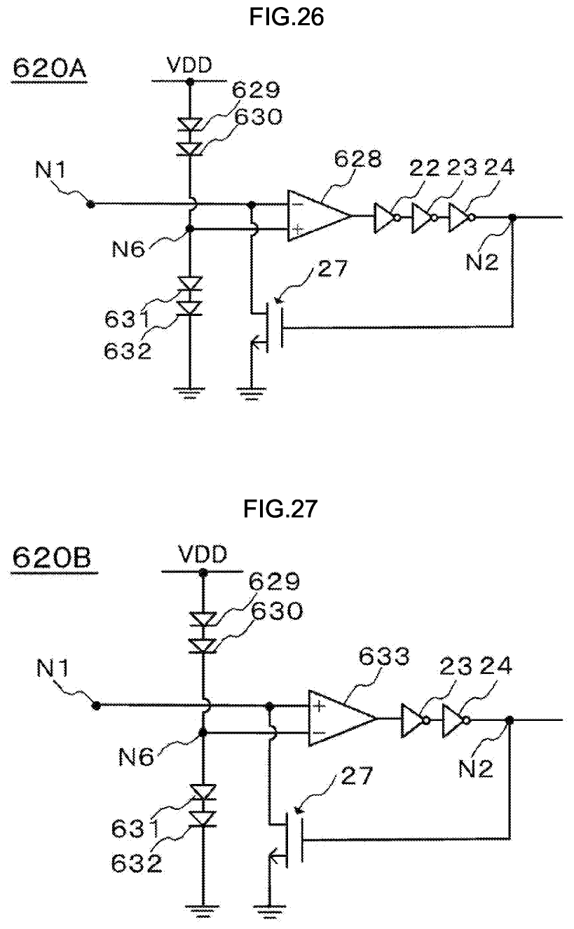

FIG. 26 is a diagram illustrating a configuration of a pulse generation circuit 620A according to a first modification of the present sixth embodiment. The pulse generation circuit 620A is obtained by replacing the first-stage inverter 21 with a comparator 628 in the pulse generation circuit 20 according to the first embodiment.

Specifically, the pulse generation circuit 620A includes inverters 22 to 24, a transistor 27 which is an N-channel MOSFET, and a comparator 628. A minus terminal of the comparator 628 is connected to an input node N1 of the pulse generation circuit 620A. A plus terminal of the comparator 628 is connected to a node N6 having an intermediate potential between a power supply line VDD and a ground GND. In the present sixth embodiment, a voltage of the node N6 is set to 0.5 V by the four diodes 629 to 632 connected in series in the forward direction.

When a voltage of an input node N1 is lower than 0.5 V that is the voltage of the node N6, the comparator 628 outputs 1 V. At this time, since the inverter 22 outputs 0 V, the inverter 23 outputs 1 V, and the inverter 24 outputs 0 V, a voltage of an output node N2 is 0 V.

When the voltage of the input node N1 becomes higher than 0.5 V that is the voltage of the node N6, the comparator 628 outputs 0 V. At this time, since the inverter 22 outputs 1 V, the inverter 23 outputs 0 V, and the inverter 24 outputs 1 V, the voltage of the output node N2 becomes 1 V. Therefore, when the voltage of the input node N1 becomes higher than 0.5 V, an output of the pulse generation circuit 620A rapidly rises from 0 V to 1 V after a certain delay time.

When the voltage of the output node N2 becomes 1 V, the transistor 27 is turned on, and the voltage of the input node N1 becomes 0 V. As a result, since the comparator 628 outputs 1 V, the inverter 22 outputs 0 V, the inverter 23 outputs 1 V, and the inverter 24 outputs 0 V, the voltage of the output node N2 becomes 0 V. As a result, the output of the pulse generation circuit 620A rapidly drops from 1 V to 0 V.

In the pulse generation circuit 620A described above, the voltage of the node N6, which is a threshold at which the output changes, can be freely set between 0 V and 1 V according to the application of the pulse generation circuit 620A.

### Second Modification

FIG. 27 is a diagram illustrating a configuration of a pulse generation circuit 620B according to a second modification of the present sixth embodiment. The pulse generation circuit 620B is obtained by replacing the first-stage inverter 21 and the second-stage inverter 22 from the top with a comparator 633 in the pulse generation circuit 20 according to the first embodiment.

Specifically, the pulse generation circuit 620B includes inverters 23 and 24, a transistor 27 which is an N-channel MOSFET, and a comparator 633. A plus terminal of the comparator 633 is connected to an input node N1 of the pulse generation circuit 620B. A minus terminal of the comparator 633 is connected to a node N6 having an intermediate potential between a power supply line VDD and a ground GND. In the present sixth embodiment, the voltage of the node N6 is set to 0.5 V.

When the voltage of the input node N1 is lower than 0.5 V that is the voltage of the node N6, the comparator 633 outputs 0 V. At this time, since the inverter 23 outputs 1 V and the inverter 24 outputs 0 V, a voltage of an output node N2 is 0 V.

When the voltage of the input node N1 becomes higher than 0.5 V that is the voltage of the node N6, the comparator 633 outputs 1 V. At this time, since the inverter 23 outputs 0 V and the inverter 24 outputs 1 V, the voltage of the output node N2 becomes 1 V. Therefore, when the input voltage becomes higher than 0.5 V, an output of the pulse generation circuit 620B rapidly rises from 0 V to 1 V after a certain delay time.

When the voltage of the output node N2 becomes 1 V, the transistor 27 is turned on, and the voltage of the input node N1 becomes 0 V. As a result, since the comparator 633 outputs 0 V, the inverter 23 outputs 1 V, and the inverter 24 outputs 0 V, the voltage of the output node N2 becomes 0 V. As a result, the output of the pulse generation circuit 620B rapidly drops from 1 V to 0 V.

Also in the pulse generation circuit 620B described above, the voltage of the node N6, which is a threshold at which the output changes, can be freely set between 0 V and 1 V according to the application of the pulse generation circuit 620B.

### Seventh Embodiment

### Pulse Generation Circuit 720

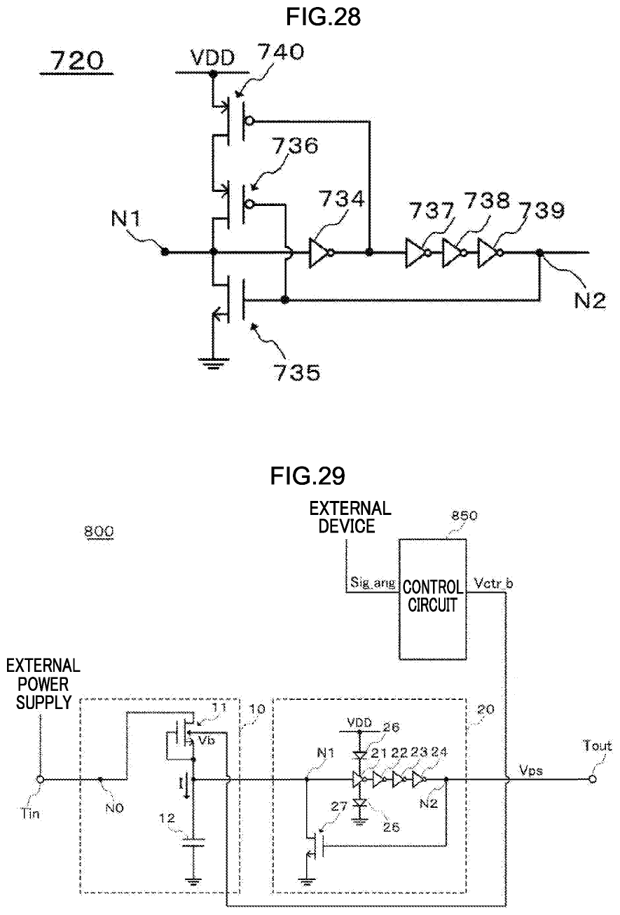

FIG. 28 is a diagram illustrating a configuration of a pulse generation circuit 720 according to the present seventh embodiment. The pulse generation circuit 720 includes a transistor 735 which is an N-channel MOSFET, a transistor 736 which is a P-channel MOSFET, an inverter 734, inverters 737 to 739 connected in multiple stages, and a transistor 740 which is a P-channel MOSFET.

A drain terminal of the transistor 735 and a drain terminal of the transistor 736 are both connected to an input node N1. A gate terminal of the transistor 735 and a gate terminal of the transistor 736 are both connected to an output node N2. A source terminal of the transistor 735 is grounded to a ground GND. A source terminal of the transistor 736 is connected to a drain terminal of the transistor 740, and a source terminal of the transistor 740 is connected to a power supply line VDD. Therefore, when the transistor 740 is on, the transistors 735 and 736 function as inverters whose inputs are connected to the output node N2 and whose outputs are connected to the input node N1.

An input terminal of the inverter 734 is connected to the input node N1. An output terminal of the inverter 734 is connected to the gate terminal of the transistor 740 and an input terminal of a first stage of the three inverters 737 to 739 connected in multiple stages. An output terminal of a last stage of the three inverters 737 connected in multiple stages is connected to the output node N2.

When the voltage of the input node N1 is 0 V, the inverter 734 outputs 1 V. At this time, since the inverter 737 outputs 0 V, the inverter 738 outputs 1 V, and the inverter 739 outputs 0 V, a voltage of the output node N2 is 0 V. Since the output of the inverter 734 is 1 V, the transistor 740 is turned off.

When the voltage of the input node N1 gradually rises and reaches a predetermined threshold voltage at which the output of inverter 734 is inverted, the output of the inverter 734 becomes 0 V. At this time, the transistor 740 is turned on, the inverter including the transistors 735 and 736 operates, and the voltage of the node N1, which is the output thereof, rapidly rises to 1 V.

In parallel with this, the inverter 737 outputs 1 V, the inverter 738 outputs 0 V, and the inverter 739 outputs 1 V, so that the voltage of the output node N2 becomes 1 V. Therefore, when the voltage of the input node N1 reaches a predetermined threshold voltage, the voltage of the output node N2 rapidly rises from 0 V to 1 V after a certain delay.

When the voltage of the output node N2 becomes 1 V, the voltage of the node N1, which is the output of the inverter including the transistors 735 and 736, rapidly drops from 1 V to 0 V. As a result, the output of the inverter 734 becomes 1 V, and the transistor 740 is turned off, so that the operation of the inverter including the transistors 735 and 736 is stopped.

In parallel with this, the inverter 737 outputs 0 V, the inverter 738 outputs 1 V, and the inverter 739 outputs 0 V, so that the voltage of the output node N2 becomes 0 V. Therefore, when the voltage of the output node N2 rapidly rises from 0 V to 1 V, the voltage of the output node N2 rapidly drops from 1 V to 0 V after a certain delay.

As described above, the pulse signal is generated by the pulse generation circuit 720. In the pulse generation circuit 720, a path from the input node N1 returning to the input node N1 via the inverter 734, the transistor 740, and the inverter including the transistors 735 and 736 forms a positive feedback loop that accelerates the rise of the voltage of the input node N1 to make the rise of the pulse signal steep.

A path from the input node N1 returning to the input node N1 via the inverter 734, the inverters 737 to 739 connected in multiple stages, the output node N2, and the inverter including the transistors 735 and 736 forms a negative feedback loop that rapidly drops the voltage of the input node N1 to make a fall of the pulse signal steep.

As described above, the pulse generation circuit 720 according to the present seventh embodiment includes the positive feedback loop that makes the rise of the pulse signal steep and the negative feedback loop that makes the fall of the pulse signal steep. As a result, a pulse signal having a narrow pulse width and a sharp waveform can be generated. When the transistor 740 is off, a through current does not flow through the inverter configured by the transistors 735 and 736, and thus power consumption is reduced.

### Eighth Embodiment

### Spiking Neuron Circuit System 800

Next, a spiking neuron circuit system 800 according to an eighth embodiment of the present disclosure will be described.

FIG. 29 is a diagram illustrating a configuration of a spiking neuron circuit system 800 according to an eighth embodiment of the present disclosure. The spiking neuron circuit system 800 places arbitrary information on a pulse signal sequence Vps and output it by controlling a pulse interval of the pulse signal sequence Vps output from the pulse generation circuit 20. In other words, the spiking neuron circuit system 800 performs “pulse interval modulation” for modulating the pulse interval of the pulse signal sequence Vps as a carrier wave.

The spiking neuron circuit system 800 includes a charging circuit 10, a pulse generation circuit 20, and a control circuit 850. An analog signal Sig_ang as a time-varying input signal is input to the control circuit 850 from an external device (not shown). As an example, the external device (not shown) is a temperature sensor, and the time-varying analog signal Sig_ang includes information of a temperature detected by the temperature sensor. However, the external device (not shown) and the time-varying analog signal Sig_ang are not limited thereto. The charging circuit 10 and the pulse generation circuit 20 are the same as those in the first embodiment. The CR time constant circuit 30, the reference signal circuit 40, and the OR gate 60 existing in the first embodiment do not exist.

A DC voltage of 1 V is continuously applied to an input terminal Tin of the spiking neuron circuit system 800 by an external power supply (not shown). Therefore, the DC voltage of 1 V is continuously input to the charging circuit 10. As a result, the charging circuit 10 repeats charging and discharging at a constant time period, and the pulse generation circuit 20 outputs a pulse signal example Vps at constant intervals.

### Control Circuit 850

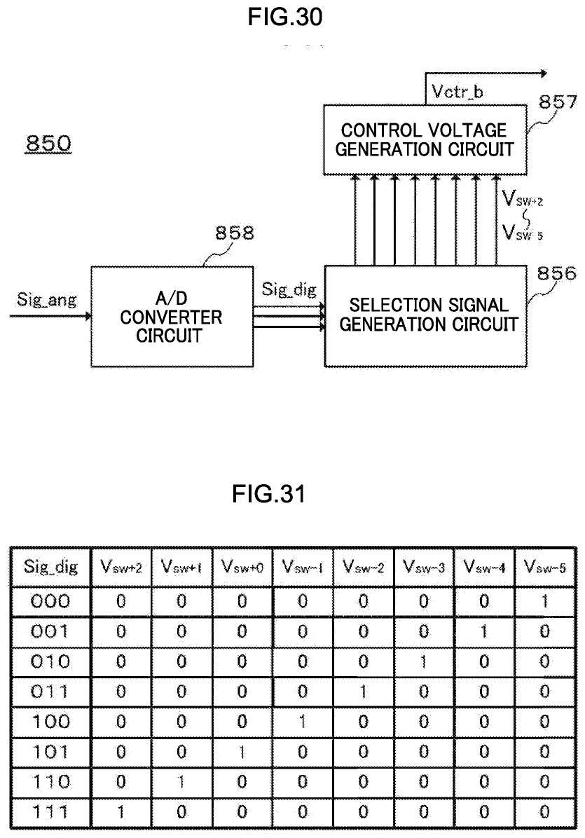

The control circuit 850 controls a pulse interval of the pulse signal sequence Vps output from the pulse generation circuit 20 by controlling the bulk voltage Vb of the transistor 11 included in the charging circuit 10 based on the time-varying analog signal Sig_ang input from the external device (not shown). FIG. 30 is a diagram illustrating an internal configuration of the control circuit 850. The control circuit 850 includes an A/D converter circuit 858, a selection signal generation circuit 856, and a control voltage generation circuit 857.

### A/D Converter Circuit 858

When the time-varying analog signal Sig_ang is input, the A/D converter circuit 858 samples and quantizes the signal at constant time intervals, converts the signal into a 3-bit digital signal Sig_dig, and outputs the converted signal. As the configuration of the A/D converter circuit 858, various well-known circuit configurations can be adopted.

### Selection Signal Generation Circuit 856

The selection signal generation circuit 856 generates and outputs the eight selection signals Vsw+2 to Vsw−5 based on the 3-bit digital signal Sig_dig output from the A/D converter circuit 858. These eight selection signals Vsw+2 to Vsw−5 are signals in which only one of them is 1 V and the others are all 0 V, corresponding to the 3-bit digital signal Sig_dig. FIG. 31 is a diagram illustrating a correspondence relationship between inputs and outputs of the selection signal generation circuit 856.

### Control Voltage Generation Circuit 857

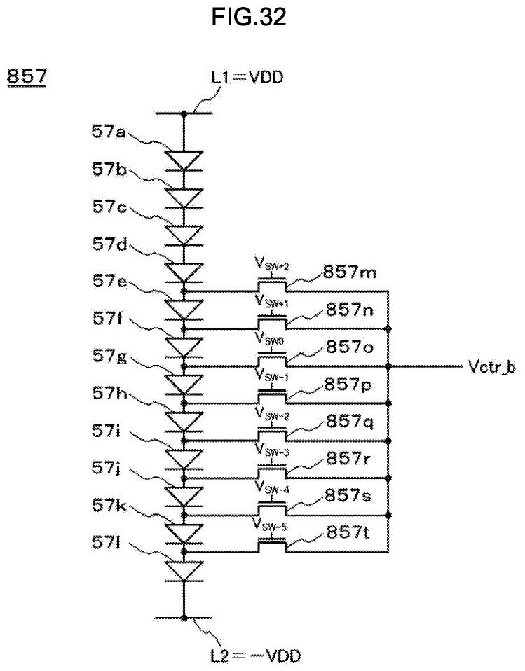

FIG. 32 is a diagram illustrating an internal configuration of the control voltage generation circuit 857. The control voltage generation circuit 857 includes twelve diodes 57a to 57l and eight switches 857m to 857t. The control voltage generation circuit 857 generates and outputs a bulk control voltage Vctr_b that changes in eight stages based on the eight selection signals Vsw+2 to Vsw−5 output from the selection signal generation circuit 856.

Returning to FIG. 29, the bulk control voltage Vctr_b that is output from the control circuit 850 and changes in eight stages is applied to the bulk terminal of the transistor 11 included in the charging circuit 10, and the bulk voltage Vb of the transistor 11 changes in eight stages. As the bulk voltage Vb of the transistor 11 changes in eight stages, the pulse interval of the pulse signal sequence Vps output from the pulse generation circuit 20 changes in eight stages. As a result, the pulse interval of the pulse signal sequence Vps changes in eight stages based on the analog signal Sig_ang input from the external device (not shown). In other words, the pulse interval of the pulse signal sequence Vps is controlled in eight stages based on the analog signal Sig_ang input from an external device (not shown).

As described above, the spiking neuron circuit 800 according to the present eighth embodiment controls the pulse interval of the pulse signal sequence Vps output from the pulse generation circuit 20 based on the analog signal Sig_ang as the time-varying input signal. As a result, the information of the analog signal Sig_ang can be placed on the pulse signal sequence Vps and transmitted. The pulse signal example Vps for which the pulse interval is controlled can be used, for example, for controlling a switching frequency of a step-up chopper circuit or a step-down chopper circuit. Impedance matching can be performed with the power supply element by this control.

The output of the A/D converter circuit 858 is not limited to 3 bits, and may be 2 bits or less, or 4 bits or more. The number of selection signals output from the selection signal generation circuit 856 and the number of switches of the control voltage generation circuit 857 are determined according to the number of bits output from the A/D converter circuit 858. The signal input from the external device may be a digital signal instead of an analog signal. In this case, the A/D converter circuit 858 can be omitted.

By combining the present eighth embodiment and the second embodiment, the pulse interval of the pulse signal Vps sequence may be controlled by controlling the bulk voltage Vb of the P-channel MOSFET included in the charging circuit. By combining the present eighth embodiment with the third embodiment or the fourth embodiment, the pulse interval of the pulse signal Vps sequence may be controlled by controlling the gate voltage Vg of the N-channel type or P-channel MOSFET included in the charging circuit.

In the present eighth embodiment, an example in which the CR time constant circuit 30, the reference signal circuit 40, and the OR gate 60 existing in the first embodiment do not exist has been described. By combining the CR time constant circuit 30, the reference signal circuit 40, and the OR gate 60 existing in the first embodiment with the present eighth embodiment, the control circuit 850 of the eighth embodiment may further perform control after performing so-called calibration operation performed in the first embodiment on the control voltage of the transistor 11 included in the charging circuit 10. In such a case, arbitrary information to be transmitted can be transmitted more accurately.

### Ninth Embodiment

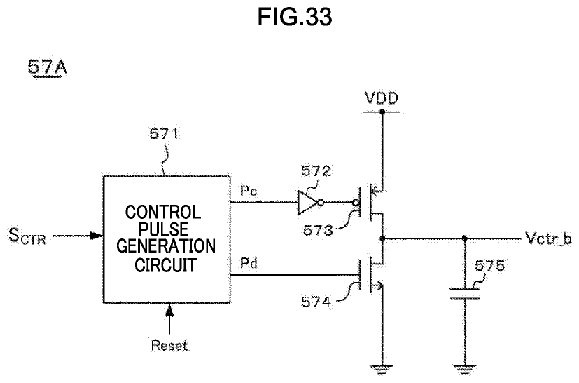

FIG. 33 is a diagram illustrating an example of a configuration of a control voltage generation circuit 57A according to a ninth embodiment. The control voltage generation circuit 57A has a control pulse generation circuit 571, a NOT gate 572, a transistor 573 which is a P-channel MOSFET, a transistor 574 which is an N-channel MOSFET, and a capacitor 575.

A selection signal Vsw including a plurality of bits output from the selection signal generation circuit 56 (see FIG. 3) is input to the control pulse generation circuit 571. The control pulse generation circuit 571 outputs a charge control pulse Pc whose pulse width is determined according to a value of the selection signal Vsw. A reset signal Reset output from the reset generation circuit 53 (see FIG. 3) is input to the control pulse generation circuit 571. The control pulse generation circuit 571 outputs a discharge control pulse Pd in response to the reset signal Reset.

The charge control pulse Pc is supplied to a gate terminal of the transistor 573 via the NOT gate 572. The discharge control pulse Pd is supplied to a gate terminal of the transistor 574. A source terminal of the transistor 573 is connected to a power supply line VDD, and a drain terminal is connected to a drain terminal of the transistor 574 and one end of the capacitor 575. A source terminal of the transistor 574 is grounded to a ground GND. One end of the capacitor 575 is an output node of a bulk control voltage Vctr_b. The other end of the capacitor 575 is grounded to the ground GND.

The transistor 573 is turned on for a period corresponding to the pulse width of the charge control pulse Pc. When the transistor 573 is turned on, the capacitor 575 is charged. The charged voltage of the capacitor 575 is output as the bulk control voltage Vctr_b. The level of the charged voltage of the capacitor 575 corresponds to an ON period of the transistor 573. That is, the level of the bulk control voltage Vctr_b is controlled by the pulse width and the number of pulses of the charge control pulse Pc. The control voltage generation circuit 57 according to the first embodiment described above controls the bulk control voltage Vctr_b in five stages according to the five selection signals Vsw+2 to Vsw−2. On the other hand, in the control voltage generation circuit 57A according to the present ninth embodiment, the bulk control voltage Vctr_b can be controlled in five or more stages by a control signal S_{CTR}. The control pulse generation circuit 571 may intermittently update the charged voltage of the capacitor 575 in real time by intermittently outputting the charge control pulse Pc according to the intermittently supplied control signal S_{CTR}. The control signal S_{CTR} may be a pulse signal having a fixed width of 1 bit.

In this regard, the transistor 574 is turned on in response to the reset signal Reset. That is, the transistor 574 is turned on at a timing at which the level of the bulk control voltage Vctr_b should be switched. When the transistor 574 is turned on, the charge accumulated in the capacitor 575 is discharged. As a result, the level of the bulk control voltage Vctr_b decreases.

According to the control voltage generation circuit 57 according to the first embodiment described above, a step width of the voltage when controlling the bulk control voltage Vctr_b is determined by the number of diodes connected in series between the first power supply line L1 and the second power supply L2. The step width of the voltage when controlling the bulk control voltage Vctr_b cannot be made smaller than the forward voltage of the diode. In this regard, according to the control voltage generation circuit 57A of the present ninth embodiment, since the charged voltage of the capacitor 575 is output as the bulk control voltage Vctr_b, it is possible to achieve the step width of the voltage when controlling the bulk control voltage Vctr_b without adding a circuit element. The bulk control voltage Vctr_b can be controlled with the step width smaller than the forward voltage of the diode.

### Tenth Embodiment

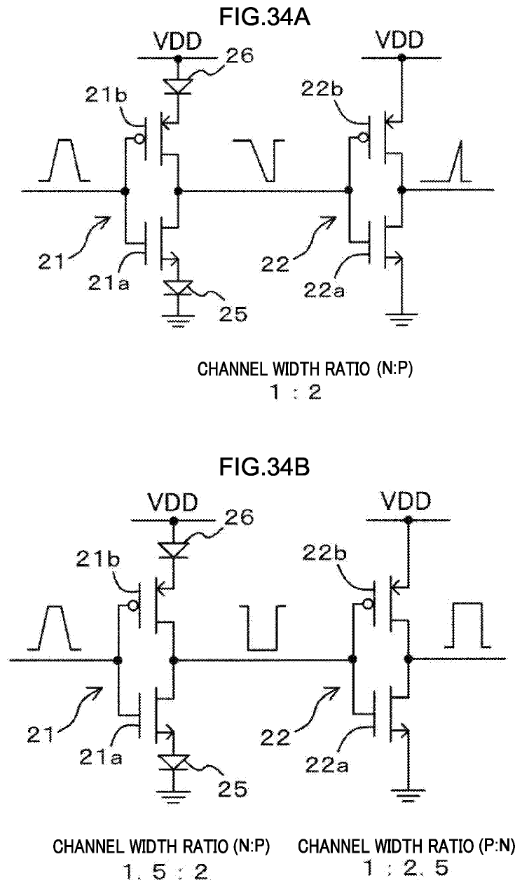

FIGS. 34A and 34B are diagrams illustrating only the first-stage inverter 21 and the second-stage inverter 22 among the plurality of inverters configuring the pulse generation circuit 20, respectively. The first-stage inverter 21 includes a transistor 21a which is an N-channel MOSFET and a transistor 21b which is a P-channel MOSFET. The transistors 21a and 21b are complementarily turned on. Similarly, the second-stage inverter 22 includes a transistor 22a which is an N-channel MOSFET and a transistor 22b which is a P-channel MOSFET. The transistors 22a and 22b are complementarily turned on.

Here, a channel width ratio of a P-channel MOSFET (hereinafter, referred to as a P-MOS) and an N-channel MOSFET (hereinafter, referred to as an N-MOS) configuring the inverter is considered. In general, a mobility of the MOSFET is higher in the N-channel type than in the P-channel type. The channel width ratio of the P-MOS and the N-MOS configuring the inverter is determined according to a mobility ratio. For example, when a mobility ratio (P:N) between the P-MOS and the N-MOS is, for example, 1:2, a channel width ratio (P:N) between the P-MOS and the N-MOS configuring the inverter can be designed to be 2:1.

FIG. 34A illustrates signal waveforms of the respective units of the inverters 21 and 22 in a case where the channel width ratio (N:P) of the N-MOS and the P-MOS is set to 1:2 according to the mobility ratio of these transistors. Here, the channel width ratio (N:P)=1:2 is set as a standard value. In this case, the width of the pulse output from each of the inverters 21 and 22 becomes narrower than the pulse width of the input pulse due to an influence of a threshold voltage variation of the MOSFET or the like, and the pulse may disappear. This problem can be solved by adjusting the channel width ratio of the P-MOS and the N-MOS configuring the inverter from the standard value. This point will be described with reference to FIG. 34B.

When a pulse signal transitioning from a high level to a low level is input to the first-stage inverter 21, the transistor 21a which is an N-MOS is turned on, and the transistor 21b which is a P-MOS is turned off. For example, by increasing the channel width of the transistor 21a to be turned on, the channel width ratio (N:P) of the transistors 21b and 21a configuring the inverter 21 is changed from the standard value of 1:2 to 1.5:2. As a result, it is possible to suppress the narrowing of the width of the pulse output from the inverter 21.

The pulse signal that is output from the first-stage inverter 21 and transitions from a high level to a low level is input to the second-stage inverter 22. When a pulse signal transitioning from a high level to a low level is input to the second-stage inverter 22, the transistor 22b which is a P-MOS is turned on, and the transistor 22a which is an N-MOS is turned off. For example, by increasing the channel width of the transistor 22b to be turned on, the channel width ratio (N:P) of the transistors 22a and 22b configuring the inverter 22 is changed from the standard value of 1:2 to 1:2.5. As a result, it is possible to suppress the narrowing of the width of the pulse output from the inverter 22. The channel width ratio in the fourth-stage (last stage) inverter 24 can be set to be a value similar to the channel width ratio in the second-stage inverter 22.

As described above, in the pulse generation circuit 20 according to the present tenth embodiment, the channel width ratios of the P-MOS and the N-MOS configuring the inverters 21 to 24 are different between adjacent inverters. As a result, the pulse width of the pulse output from each inverter is narrowed, and the problem that the pulse disappears can be solved. The above configuration can be applied not only to the pulse generation circuit 20 but also to all logic circuits such as NAND, NOR, and latch configuring the spiking neuron circuit system. The numerical value described as the channel width ratio is an example, and the channel width ratio can be appropriately changed so that the disappearance of the pulse can be prevented.

### Eleventh Embodiment

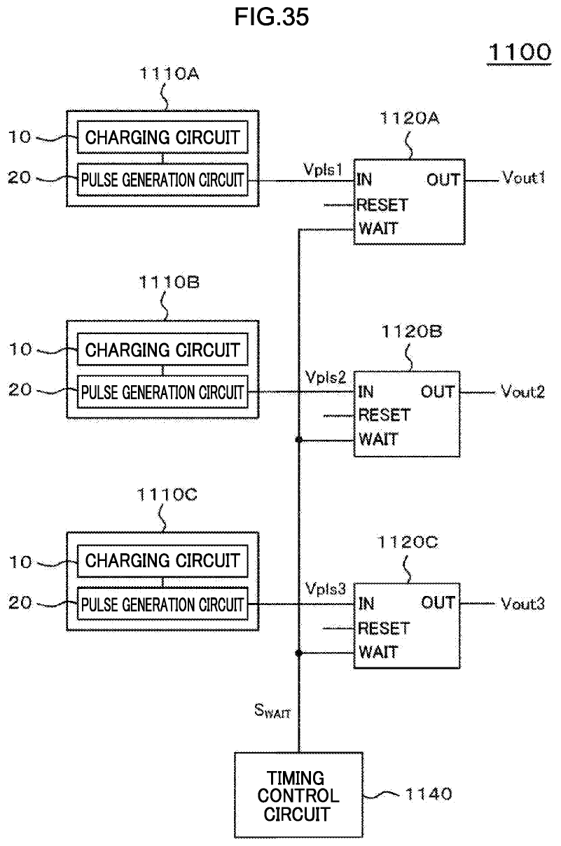

FIG. 35 is a diagram illustrating an example of a configuration of a spiking neuron circuit system 1100 according to an eleventh embodiment. The spiking neuron circuit system 1100 includes three spiking neuron circuits 1110A, 1110B, and 1110C and three output control circuits 1120A, 1120B, and 1120C.

Each of the spiking neuron circuits 1100A, 1100B, and 1100C includes a charging circuit 10 and a pulse generation circuit 20. The pulse generation circuit 20 outputs pulse signals Vpls1, Vpls2, and Vpls3, respectively. The spiking neuron circuits 1110A, 1110B, and 1110C operate independently of each other, and the pulse signals Vpls1, Vpls2, and Vpls3 output from the pulse generation circuits 20 are asynchronous to each other.

The output control circuits 1120A, 1120B, and 1120C are provided corresponding to the spiking neuron circuits 1110A, 1110B, and 1110C, respectively. The pulse signals Vpls1, Vpls2, and Vpls3 output from the spiking neuron circuits 1110A, 1110B, and 1110C are input to input terminals (IN) of the corresponding output control circuits 1120A, 1120B, and 1120C, respectively. The output control circuits 1120A, 1120B, and 1120C output output signals Vout1, Vout2, and Vout3 whose states transition at timings corresponding to the corresponding pulse signals Vpls1, Vpls2, and Vpls3, respectively, from the output terminals (OUT). A common standby signal S_{WAIT} output from a timing control circuit 1140 is input to control terminals (WAIT) of the output control circuits 1120A, 1120B, and 1120C. When the standby signal S_{WAIT} is input, each of the output control circuits 1120A, 1120B, and 1120C holds the states of the output signals Vout1, Vout2, and Vout3 in a standby period indicated by the standby signal S_{WAIT}. That is, the transition of the states of the output signals Vout1, Vout2, and Vout3 is prohibited in the standby period.

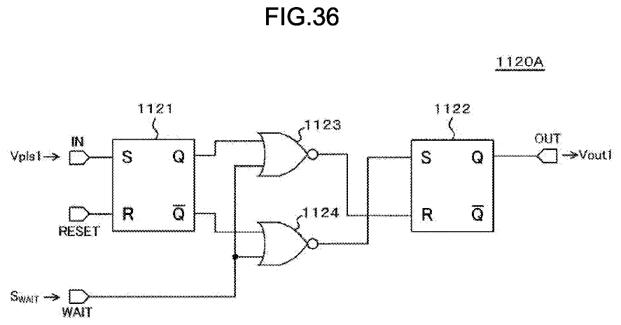

FIG. 36 is a diagram illustrating an example of an internal configuration of the output control circuit 1120A. The configurations of the output control circuits 1120A, 1120B, and 1120C are the same. The output control circuit 1120A includes two SR latches 1121 and 1122 and two NOR gates 1123 and 1124. An S terminal of the SR latch 1121 is an input terminal (IN) of the output control circuit 1120A, and a pulse signal Vpls1 is input to the S terminal. An R terminal of the SR latch is a reset terminal (RESET) of the output control circuit 1120A, and a reset signal for resetting the output signal Vout1 is input to the R terminal. A Q terminal of the SR latch 1121 is connected to one input terminal of the NOR gate 1123. A/Q terminal of the SR latch 1121 is connected to one input terminal of the NOR gate 1124. The/Q terminal is a terminal that outputs a signal obtained by inverting the logic of the signal output from the Q terminal.

The other input terminals of the NOR gates 1123 and 1124 are control terminals (WAIT) of the output control circuit 1120A, and the standby signal S_{WAIT} is input to these input terminals. An output terminal of the NOR gate 1123 is connected to an S terminal of the SR latch 1122, and an output terminal of the NOR gate 1124 is connected to an R terminal of the SR latch 1122. A Q terminal of the SR's latch 1122 is an output terminal (OUT) of the output control circuit 1120A.

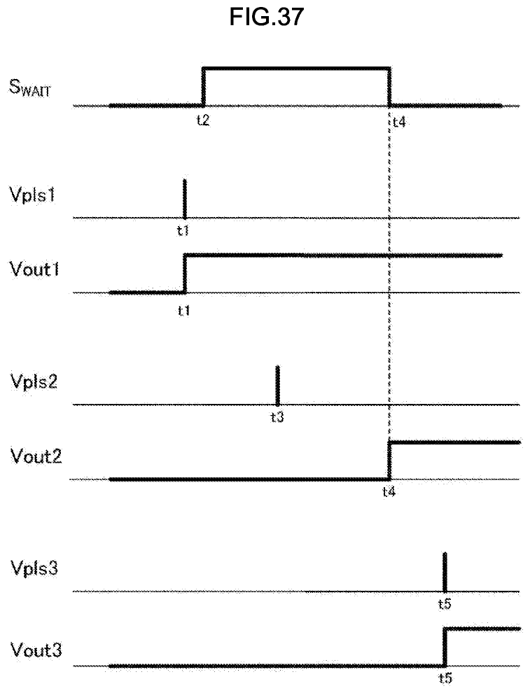

FIG. 37 is a timing chart illustrating an example of an operation of the spiking neuron circuit system 1100 according to the present eleventh embodiment. FIG. 37 illustrates a case where the standby signal S_{WAIT} is set to a high level during a period from time t2 to time t4, the spiking neuron circuit 1110A outputs the pulse signal Vpls1 at time t1 before time t2, the spiking neuron circuit 1110B outputs the pulse signal Vpls2 at time t3 after time t2 and before time t4, and the spiking neuron circuit 1110C outputs the pulse signal Vpls3 at time t5 after time t4. A period from time t2 to time t4 in which the standby signal S_{WAIT} becomes a high level is a standby period in which the states of the output signals Vout1, Vout2, and Vout3 are maintained.

The output control circuit 1120A causes the output signal Vout1 to transition to a high level according to the pulse signal Vpls1 at time t1. The pulse signal Vpls2 is input to the output control circuit 1120B at time t3, but since time t3 is in the standby period, the output control circuit 1120B does not cause the output signal Vout2 to transition to a high level but holds the output signal Vout2 in the immediately preceding state (low level). The output control circuit 1120B causes the output signal Vout2 to transition to a high level at time t4 when the standby period ends. The output control circuit 1120C causes the output signal Vout3 to transition to a high level according to the pulse signal Vpls3 at time t5.

According to the spiking neuron circuit system 1100 according to the present eleventh embodiment, for example, while a process with high priority is being executed, transition of the states of the output signals Vout1, Vout2, and Vout3 is prohibited, whereby the circuit operation can be appropriately maintained.

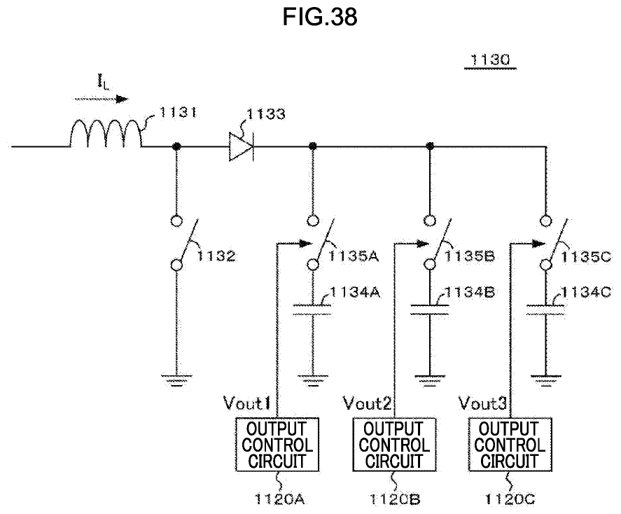

FIG. 38 is a diagram illustrating an example of a configuration of a booster circuit 1130 controlled by the spiking neuron circuit system 1100 according to the present eleventh embodiment. The booster circuit 1130 includes an inductor 1131, a switch 1132 for current control, a diode 1133, capacitors 1134A, 1134B, and 1134C, and switches 1135A, 1135B, and 1135C for capacitor selection. The switches 1135A, 1135B, and 1135C are controlled by the output signals Vout1, Vout2, and Vout3 of the spiking neuron circuit system 1100 (output control circuits 1120A, 1120B, 1120C, see FIG. 35), respectively. When the switches 1135A, 1135B, and 1135C are turned on, the corresponding capacitors 1134A, 1134B, and 1134C are charged by a current I_{L} flowing through the inductor 1131.

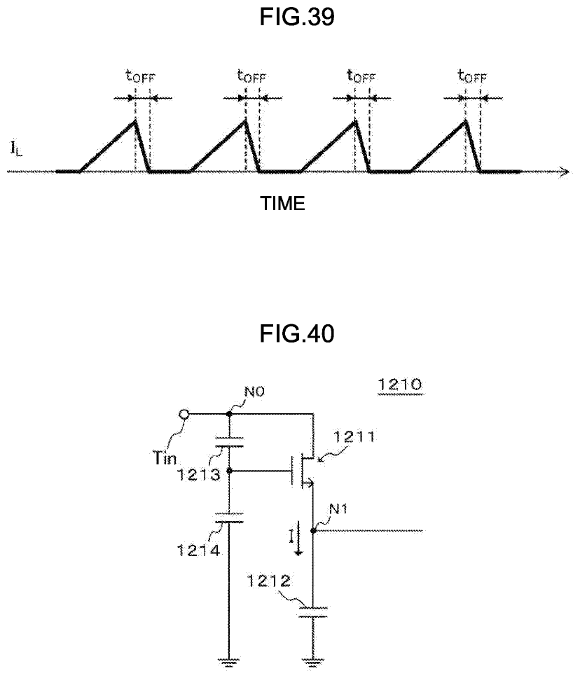

FIG. 39 is a waveform diagram of the current I_{L} flowing through the inductor 1131. When the switch 1132 is turned on, the current I_{L} increases, and when the switch 1132 is turned off, the current I_{L} decreases. In an off-period t_{OFF} in which the switch 1132 is in an off-state, when all of the switches 1135A, 1135B, and 1135C are in the off-state, there is no place where the current I_{L} goes, the voltage rapidly rises, and the booster circuit 1130 may be damaged. The spiking neuron circuit system 1100 according to the present eleventh embodiment prohibits the transition of the states of the output signals Vout1, Vout2, and Vout3 in the off-period t_{OFF}, and prevents all of the switches 1135A, 1135B, and 1135C from being turned off, so that the above problem can be avoided. In the above description, the case where the output signals Vout1, Vout2, and Vout3 of the spiking neuron circuit system 1100 (output control circuits 1120A, 1120B, and 1120C) are used to select the capacitors 1134A, 1134B, and 1134C in the booster circuit 1130 has been exemplified. However, the spiking neuron circuit system 1100 according to the present embodiment can be used for other purposes. For example, it is also possible to use a plurality of functional blocks exhibiting a predetermined function included in an integrated circuit for the purpose of selectively enabling the functional blocks. The number of the pulse generation circuits and the output control circuits, and the generation timings of the pulse signal and the output signal can be appropriately changed according to the purpose of use.

### Twelfth Embodiment

FIG. 40 is a diagram illustrating an example of a configuration of a charging circuit 1210 according to a twelfth embodiment. The charging circuit 1210 includes a transistor 1211 which is an N-channel MOSFET and a capacitor 1212 as a capacitance component. A drain terminal of the transistor 1211 is connected to an input node N0 of the charging circuit 1210, and the input node N0 is connected to an input terminal Tin. A source terminal of the transistor 1211 is connected to one terminal of the capacitor 1212. The other terminal of the capacitor 1212 is grounded to a ground GND.

The charging circuit 1210 according to present twelfth embodiment includes capacitors 1213 and 1214. The capacitor 1213 has one end connected to a drain terminal of the transistor 1211 and the other end connected to a gate terminal of the transistor 1211. The capacitor 1214 has one end connected to the gate terminal of the transistor 1211 and the other end grounded to the ground GND. A voltage determined according to a capacitance ratio of the capacitor 1213 and the capacitor 1214 is applied to the gate terminal of the transistor 1211.

The charging circuit 10 according to the first embodiment described above performs charging of the capacitor 12 by an off-current of the transistor 11. According to this embodiment, there is a possibility that a control range of the waiting time from when the input voltage is applied to when the pulse signal is output cannot be sufficiently secured. In this regard, according to charging circuit 1210 of the present twelfth embodiment, a voltage determined according to the capacitance ratio of capacitor 1213 and capacitor 1214 is applied to the gate terminal of transistor 1211, and transistor 1211 is used in a subthreshold state, so that the control range of the waiting time can be widened. According to the charging circuit 1210 of the present twelfth embodiment, the output current (that is, the charging current of the capacitor 1212) of the transistor 1211 can be controlled in a range of 1 pA to 10 nA, for example. When the charging circuit 1210 according to the twelfth embodiment is applied to the spiking neuron circuit system, a control circuit for controlling the output current of the transistor 1211 may be omitted. In this regard, the spiking neuron circuit system may include both the charging circuit 1210 according to the present twelfth embodiment and a control circuit that controls the voltage of a back gate of the transistor 1211 and is similar to the control circuit (for example, control circuit 50 illustrated in FIG. 1, control circuit 250 illustrated in FIG. 14, and control circuit 850 illustrated in FIG. 29) described in the previous embodiment. For example, the output current of the transistor 1211 may be roughly adjusted by the capacitance ratio of the capacitor 1213 and the capacitor 1214, and fine adjustment may be performed to compensate for process variations and temperature dependency of the transistor 1211 by a control circuit that controls the voltage of the back gate of the transistor 1211.

The present disclosure of Japanese Patent Application No. 2021-111124 filed on Jul. 2, 2021 is incorporated herein by reference in their entirety. All documents, patent applications, and technical standards described in this specification are incorporated herein by reference to the same extent as if each document, patent application, and technical standard were specifically and individually indicated to be incorporated by reference.

1. A spiking neuron circuit system, comprising:
a charging circuit that, when an input voltage is applied, starts charging of a capacitance component by an output current of a field effect transistor;
a pulse generation circuit that generates and outputs a pulse signal when a charged voltage of the capacitance component reaches a first predetermined value; and
a control circuit that controls the output current of the field effect transistor by controlling at least one of a bulk voltage or a gate voltage of the field effect transistor.

2. The spiking neuron circuit system according to claim 1, wherein the control circuit includes a control voltage generation circuit that generates a control voltage for controlling the at least one of the bulk voltage or the gate voltage of the field effect transistor.

3. The spiking neuron circuit system according to claim 2, wherein:
the control circuit further includes a selection signal generation circuit that generates a selection signal for generation of the control voltage by the control voltage generation circuit, and
the selection signal generation circuit has a storage circuit that stores information for generating the selection signal.

4. The spiking neuron circuit system according to claim 2, wherein the control circuit discretely controls the at least one of the bulk voltage or the gate voltage of the field effect transistor.

5. The spiking neuron circuit system according to claim 2, wherein the control voltage generation circuit includes a plurality of diodes connected in series in a forward direction between a first power supply line and a second power supply line, and generates any one of voltages generated at respective nodes between the diodes as the control voltage.

6. The spiking neuron circuit system according to claim 2, wherein the control voltage generation circuit includes a capacitor and generates a charged voltage of the capacitor as the control voltage.

7. The spiking neuron circuit system according to claim 1, further comprising a reference signal circuit that outputs a reference signal when a predetermined time elapses after the input voltage is applied,
wherein the control circuit compensates for a waiting time from when the input voltage is applied to when the pulse signal is output based on a time difference between a timing at which the reference signal is output and a timing at which the pulse signal is output.

8. The spiking neuron circuit system according to claim 7, wherein a variation of the predetermined time with respect to a temperature change is smaller than a variation of the waiting time with respect to a temperature change.

9. The spiking neuron circuit system according to claim 7, wherein:
the charging circuit is mounted on a semiconductor substrate,
the spiking neuron circuit system further comprises a time constant circuit that includes a resistor and a capacitor configured by individual elements externally attached to the semiconductor substrate and that charges the capacitor with a predetermined time constant, and
the reference signal circuit outputs the reference signal when a charged voltage of the capacitor reaches a second predetermined value.

10. The spiking neuron circuit system according to claim 9, further comprising a switch that controls power supply to the resistor and the capacitor,
wherein the switch allows power supply to the resistor and the capacitor only when compensating for the waiting time.

11. The spiking neuron circuit system according to claim 10, wherein the control circuit switches a voltage to be supplied to at least one of a bulk terminal or a gate terminal of the field effect transistor, in stages, until a time difference between a timing at which the reference signal is output and a timing at which the pulse signal is output becomes equal to or less than a third predetermined value.

12. The spiking neuron circuit system according to claim 11, wherein:
the control circuit further includes a control voltage generation circuit that generates a control voltage for controlling the at least one of the bulk voltage or the gate voltage of the field effect transistor, and includes a selection signal generation circuit that generates a selection signal for generation of the control voltage by the control voltage generation circuit, and ends compensation for the waiting time when the time difference between the timing at which the reference signal is output and the timing at which the pulse signal is output becomes equal to or less than the third predetermined value, and
the selection signal generation circuit has a storage circuit that stores information for generating the selection signal, and stores the information for generating the selection signal at the end of the compensation for the waiting time in the storage circuit.

13. The spiking neuron circuit system according to claim 1, wherein the capacitance component of the charging circuit includes a parasitic capacitance of a transistor.

14. The spiking neuron circuit system according to claim 1, wherein the control circuit controls the output current of the field effect transistor by controlling the bulk voltage.

15. The spiking neuron circuit system according to claim 14, wherein:
the field effect transistor is an N-channel type, and
the control circuit controls the bulk voltage in a range of −VDD to 0.4 VDD, when VDD is a power supply voltage of the spiking neuron circuit system.

16. The spiking neuron circuit system according to claim 14, wherein:
the field effect transistor is a P-channel type, and
the control circuit controls the bulk voltage in a range of 0.6 VDD to 2 VDD, when VDD is a power supply voltage of the spiking neuron circuit system.

17. The spiking neuron circuit system according to claim 1, wherein the control circuit controls the output current of the field effect transistor by controlling the gate voltage.

18. The spiking neuron circuit system according to claim 17, wherein the control circuit controls the gate voltage in a range of 0 to VDD, when VDD is a power supply voltage of the spiking neuron circuit system.

19. The spiking neuron circuit system according to claim 1, wherein the pulse generation circuit has a positive feedback loop and a negative feedback loop.

20. The spiking neuron circuit system according to claim 19, wherein the positive feedback loop steepens a rise of the pulse signal, and the negative feedback loop steepens a fall of the pulse signal.

21. The spiking neuron circuit system according to claim 1, wherein:
the pulse generation circuit includes a plurality of inverters connected in a cascade,
each of the plurality of inverters includes a P-channel field effect transistor and an N-channel field effect transistor that are complementarily turned on, and
channel width ratios of the P-channel field effect transistor and the N-channel field effect transistor are different from each other between adjacent inverters.

22. The spiking neuron circuit system according to claim 1, further comprising:
a timing control circuit that outputs a standby signal; and
a plurality of output control circuits, each of which corresponds to at least one of the pulse generation circuits, and each of which outputs an output signal having a state that transitions at a timing corresponding to a pulse signal output from the corresponding pulse generation circuit, and holds a state of the output signal during a standby period indicated by the standby signal when the standby signal is input.

23. The spiking neuron circuit system according to claim 1, further comprising a switching element connected to the capacitance component, wherein:
a pulse signal sequence is output from the pulse generation circuit by repeating charging of the capacitance component by the charging circuit and discharging of the capacitance component by the switching element, and
the control circuit controls a pulse interval of the pulse signal sequence output from the pulse generation circuit.

24. The spiking neuron circuit system according to claim 23, wherein the control circuit controls the pulse interval of the pulse signal sequence based on information to be transmitted.

25. The spiking neuron circuit system according to claim 24, wherein the information to be transmitted is a time-varying input signal.

26. A spiking neuron circuit, comprising:
a charging circuit that, when an input voltage is applied, starts charging of a capacitance component by an output current of a field effect transistor;
a plurality of inverters connected between an input node connected to the capacitance component and an output node from which a pulse signal is output; and
a switching element provided between the input node and a first reference voltage and having a control terminal connected to the output node,
wherein the spiking neuron circuit does not have a feedback loop that feeds back from connecting points between inverters in the plurality of inverters to the input node.

27. A spiking neuron circuit according to claim 26, wherein:
a first-stage inverter of the plurality of inverters includes a first switching element provided between the first reference voltage and an intermediate output node, and a second switching element provided between the intermediate output node and a second reference voltage, and
a first diode is connected in a forward direction between the first reference voltage and the first switching element, and a second diode is connected in a forward direction between the second switching element and the second reference voltage.

28. The spiking neuron circuit according to claim 27, further comprising a comparator having one input terminal connected to the input node, the other input terminal connected to a predetermined intermediate potential between the first reference voltage and the second reference voltage, and an output terminal connected to an input terminal of the first-stage inverter of the plurality of inverters.

29. A spiking neuron circuit according to claim 26, wherein the charging circuit includes a plurality of capacitors, and a voltage determined according to a capacitance ratio of the plurality of capacitors is applied to a gate terminal of the field effect transistor.
